(19) United States
(12) Patent Application Publication
(10) Pub. No.: US 2017/0062749 A1
(43) Pub. Date: Mar. 2, 2017

(54) Light-Emitting Element, Light-Emitting Device, Electronic Device, and Lighting Device

(71) Applicant: Semiconductor Energy Laboratory Co., Ltd., Kanagawa-ken (JP)

(72) Inventors: Satoshi Seo, Sagamihara (JP); Tetsuo Tsutsui, Kasuga (JP); Takao Hamada, Takaoka (JP); Tomoya Hirose, Atsugi (JP)

(73) Assignee: Semiconductor Energy Laboratory Co., Ltd., Kanagawa-ken (JP)

(21) Appl. No.: 15/251,275

(22) Filed: Aug. 30, 2016

(30) Foreign Application Priority Data
Sep. 1, 2015 (JP) 2015-172107
Nov. 30, 2015 (JP) 2015-233260
Mar. 15, 2016 (JP) 2016-050742

(51) Int. Cl. H01L 51/50; H01L 27/32

(52) U.S. Cl. CPC H01L 51/502; H01L 27/3213; H01L 27/322; H01L 51/5016; H01L 51/5088; H01L 51/5056; H01L 2251/303; H01L 51/5004; H01L 2251/552; H01L 51/0074

(57) ABSTRACT

Provided is a novel light-emitting element, a light-emitting element with a long lifetime, or a light-emitting element with high luminous efficiency. The light-emitting element includes an anode, a cathode, a light-emitting layer, and a hole-injection layer. The light-emitting layer and the hole-injection layer are between the anode and the cathode. The hole-injection layer is closer to the anode than the light-emitting layer is. The light-emitting layer contains a light-emitting substance. The hole-injection layer contains a first substance which is an organic compound having a hole-transport property and a second substance which is a substance having an electron acceptor property with respect to the first substance. The light-emitting substance is a quantum dot.

### BACKGROUND OF THE INVENTION

1. Field of the Invention

One embodiment of the present invention relates to, a light-emitting element, a display module, a lighting module, a display device, a light-emitting device, an electronic device, and a lighting device. Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Thus, specific examples of the technical field of one embodiment of the present invention disclosed in this specification can include a semiconductor device, a display device, a liquid crystal display device, a light-emitting device, a lighting device, a power storage device, a memory device, an imaging device, a method for driving any of them, and a method for manufacturing any of them.

2. Description of the Related Art

A quantum dot is a semiconductor nanocrystal with a size of several nanometers and contains approximately 1×10³ to 1×10⁶ atoms. A quantum dot confines an electron, a hole, or an exciton, which results in discrete energy states and an energy shift depending on the size of a quantum dot. This means that quantum dots made of the same substance emit light with different wavelengths depending on their size; thus, emission wavelengths can be easily adjusted by changing the size of quantum dots.

A quantum dot has an emission spectrum with a narrow peak because its discreteness limits the phase relaxation, leading to emission with high color purity.

In addition, a quantum dot is said to have a theoretical internal quantum efficiency of approximately 100%, which far exceeds that of a fluorescent organic compound, i.e., 25%, and is comparable to that of a phosphorescent organic compound.

Furthermore, a quantum dot which is an inorganic compound has high inherent stability. In the present circumstances, an organic compound, in particular, a phosphorescent substance that has high excitation energy and emits light with a short wavelength, has low stability and a light-emitting element containing such a material hardly exhibits a long lifetime. For the above reasons, a light-emitting element containing quantum dots as a light-emitting material is a promising substitute for an organic EL element.

Patent Document 1 discloses a light-emitting element in which a tungsten oxide is used for a hole-injection layer and a quantum dot is used as a light-emitting substance.

### REFERENCE

### Patent Document 1

### [Patent Document] PCT International Publication No. 2012/013272 Pamphlet

### SUMMARY OF THE INVENTION

Note that since the HOMO level and the LUMO level of a quantum dot are much deeper than those of an organic light-emitting compound, electron injection from a cathode is relatively easy but hole injection from an anode is difficult; thus, it is difficult to adjust a carrier balance, leading to many disadvantages such as a reduction in luminous efficiency, an increase in driving voltage, and high possibility of a short lifetime due to a change in the carrier balance.

In view of the above, an object of one embodiment of the present invention is to provide a novel light-emitting element. Another object is to provide a light-emitting element with a long lifetime. Another object is to provide a light-emitting element with high luminous efficiency.

Another object of one embodiment of the present invention is to provide a highly reliable light-emitting device, a highly reliable electronic device, and a highly reliable display device. Another object of one embodiment of the present invention is to provide a light-emitting device, an electronic device, and a display device each with low power consumption.

It is only necessary that at least one of the above-described objects be achieved in the present invention.

One embodiment of the present invention is a light-emitting element including an anode, a cathode, a light-emitting layer, and a hole-injection layer. The light-emitting layer and the hole-injection layer are between the anode and the cathode. The hole-injection layer is closer to the anode than the light-emitting layer is. The light-emitting layer contains a light-emitting substance. The hole-injection layer contains a first substance which is an organic compound having a hole-transport property and a second substance which is a substance having an electron acceptor property with respect to the first substance. The light-emitting substance is a quantum dot.

Another embodiment of the present invention is the above light-emitting element in which a HOMO level of the first substance is greater than or equal to −7.0 eV and less than or equal to −5.7 eV and preferably greater than or equal to −7.0 eV and less than or equal to −6.0 eV.

Another embodiment of the present invention is the above light-emitting element in which the first substance has a hole mobility of greater than or equal to 10⁻⁶ cm²/Vs.

Another embodiment of the present invention is the above light-emitting element in which the first substance is one of a heterocyclic compound having a dibenzothiophene skeleton or a dibenzofuran skeleton; an aromatic hydrocarbon having one or more of a carbazole skeleton, a fluorene skeleton, a naphthalene skeleton, a phenanthrene skeleton, and a triphenylene skeleton; and an organic compound including 4 to 25 benzene rings. All rings included in the organic compound are benzene rings.

Another embodiment of the present invention is the above light-emitting element in which the first substance does not have an arylamine skeleton.

Another embodiment of the present invention is the above light-emitting element in which the second substance is a transition metal oxide or an oxide of a metal belonging to any of Groups 4 to 8 in the periodic table.

Another embodiment of the present invention is the above light-emitting element in which the second substance is one or more of a vanadium oxide, a niobium oxide, a tantalum oxide, a chromium oxide, a molybdenum oxide, a tungsten oxide, a manganese oxide, a rhenium oxide, a titanium oxide, a ruthenium oxide, a zirconium oxide, a hafnium oxide, and a silver oxide.

Another embodiment of the present invention is the above light-emitting element in which the second substance is a molybdenum oxide.

Another embodiment of the present invention is the above light-emitting element in which the quantum dot has a core-shell structure.

Another embodiment of the present invention is the above light-emitting element in which the light-emitting layer is in contact with the hole-injection layer.

Another embodiment of the present invention is the above light-emitting element further including a hole-transport layer between the light-emitting layer and the hole-injection layer. The hole-transport layer contains a third substance which is an organic compound having a hole-transport property.

Another embodiment of the present invention is a light-emitting device including the above light-emitting element, a substrate, and a transistor.

Another embodiment of the present invention is an electronic device including the above light-emitting device, and a sensor, an operation button, a speaker, or a microphone.

Another embodiment of the present invention is a lighting device including the above light-emitting device and a housing.

Note that a light-emitting device in this specification includes an image display device using a light-emitting element. The light-emitting device may be included in a module in which a light-emitting element is provided with a connector such as an anisotropic conductive film or a tape carrier package (TCP), a module in which a printed wiring board is provided at the end of a TCP attached to a light-emitting element, and a module in which an integrated circuit (IC) is directly mounted on a light-emitting element by a chip on glass (COG) method. The light-emitting device may be included in lighting equipment or the like.

In one embodiment of the present invention, a novel light-emitting element, a light-emitting element with a long lifetime, or a light-emitting element with high luminous efficiency can be provided.

In another embodiment of the present invention, a light-emitting device, an electronic device, and a display device each having high reliability can be provided. In another embodiment of the present invention, a light-emitting device, an electronic device, and a display device each with low power consumption can be provided.

Note that the description of these effects does not preclude the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIG. 1 is a schematic diagram of a light-emitting element.

FIGS. 2A and 2B are conceptual diagrams of an active matrix light-emitting device.

FIGS. 3A and 3B are conceptual diagrams of active matrix light-emitting devices.

FIG. 4 is a conceptual diagram of an active matrix light-emitting device.

FIGS. 5A and 5B are conceptual diagrams of a passive matrix light-emitting device.

FIGS. 6A and 6B illustrate a lighting device.

FIGS. 7A, 7B1, 7B2, 7C, and 7D illustrate electronic devices.

FIG. 8 illustrates a light source device.

FIG. 9 illustrates a lighting device.

FIG. 10 illustrates a lighting device.

FIG. 11 illustrates in-vehicle display devices and lighting devices.

FIGS. 12A to 12C illustrate an electronic device.

FIGS. 13A to 13C illustrate an electronic device.

FIG. 14 shows emission spectra of light-emitting elements 1 to 5.

FIG. 15 shows emission spectra of comparative light-emitting elements 1 to 4.

FIG. 16 shows luminance-normalized current efficiency characteristics of the light-emitting elements 1 to 5.

FIG. 17 shows luminance-normalized current efficiency characteristics of the comparative light-emitting elements 1 to 4.

FIG. 18 shows HOMO level-normalized current efficiency characteristics of the light-emitting elements 1 to 4 and the comparative light-emitting elements 1 to 4.

FIG. 19 illustrates an example of an energy band diagram of a light-emitting element of one embodiment of the present invention.

### DETAILED DESCRIPTION OF THE INVENTION

Embodiments of the present invention will be explained below with reference to the drawings. Note that the present invention is not limited to the following description, and it will be readily appreciated by those skilled in the art that the mode and details can be changed in various different ways without departing from the spirit and the scope of the present invention. Accordingly, the present invention should not be interpreted as being limited to the content of the embodiment below.

### Embodiment 1

A current-excitation type light-emitting element in which a quantum dot is used as a light-emitting substance (hereinafter, such an element is also referred to as a QLED element) can be formed to be light and thin, can be easily formed as a planar light source, can be used for forming a minute pixel, and can be bent, for example, like an organic EL element containing an organic compound as a light-emitting substance (hereinafter, such an element is also referred to as an OLED element). In addition, a QLED element can be comparable to or advantageous over an OLED element in color purity, lifetime, efficiency, emission wavelength selection facility, and the like. Thus, a QLED element has been actively researched.

Like an OLED element, a QLED element can emit light when the QLED element has a structure in which an EL layer that includes a light-emitting layer containing a quantum dot as a light-emitting substance is provided between an anode and a cathode and current flows in the EL layer. The EL layer may include other layers such as a hole injection/transport layer, an electron injection/transport layer, and a buffer layer, in addition to the light-emitting layer. The hole injection/transport layer and the electron injection/transport layer each have functions of transporting a carrier injected from an electrode and injecting the carrier into the light-emitting layer.

It is known that the HOMO level and the LUMO level of a quantum dot contained as a light-emitting substance in a QLED element are deeper than those of an organic compound contained as a light-emitting substance in an OLED element. Thus, electron injection from a cathode is relatively easy but hole injection is difficult, leading to many problems such as an increase in driving voltage and disruption of a carrier balance.

In view of the above, one embodiment of the present invention is a QLED element having such a structure in which an EL layer includes a hole injection/transport layer and a light-emitting layer, the hole injection/transport layer includes a hole-injection layer, and the hole-injection layer contains a first substance which is an organic compound having a hole-transport property and a second substance having an electron acceptor property with respect to the first substance. It is preferable that a layer containing a composite material of the first substance and the second substance be formed in the hole-injection layer.

In the light-emitting element of one embodiment of the present invention, when the second substance extracts an electron from an adjacent first substance, an electron appears in the second substance and a hole appears in the first substance from which an electron is extracted. By an electric field, the extracted electron flows in an anode and the hole is injected into the light-emitting layer; thus, current flows. Since current flows through this mechanism, a hole can be easily injected into the light-emitting layer whose light-emitting substance is a quantum dot having a deep HOMO level; accordingly, driving voltage can be reduced and/or a carrier balance (i.e., luminous efficiency and lifetime) can be improved.

Note that a material having a deep HOMO level is preferably used as the first substance so as to facilitate hole injection into the light-emitting layer. Specifically, it is preferable to use a material having a hole-transport property whose HOMO level is −7.0 eV to −5.7 eV, preferably −7.0 eV to −6.0 eV. Note that the hole mobility as the hole-transport property of the material is preferably greater than or equal to 10⁻⁶ cm²/Vs.

The second substance can be any substance as long as it has an electron acceptor property with respect to the first substance and is preferably a transition metal oxide, an oxide of a metal belonging to any of Groups 4 to 8 in the periodic table, an organic compound having an electron-withdrawing group (a halogen group or a cyano group), or the like. A transition metal oxide or an oxide of a metal belonging to any of Groups 4 to 8 in the periodic table, specifically a vanadium oxide, a niobium oxide, a tantalum oxide, a chromium oxide, a molybdenum oxide, a tungsten oxide, a manganese oxide, a rhenium oxide, a titanium oxide, a ruthenium oxide, a zirconium oxide, a hafnium oxide, or a silver oxide, is particularly preferable because the electron acceptor property thereof is so high that an electron acceptor property is exhibited with respect to an organic compound whose HOMO level is greater than or equal to −7.0 eV and less than or equal to −5.7 eV, especially with respect to an organic compound whose HOMO level is less than or equal to −6.0 eV. It is particularly suitable to use a molybdenum oxide because of its low hygroscopicity, high chemical stability, and low toxicity.

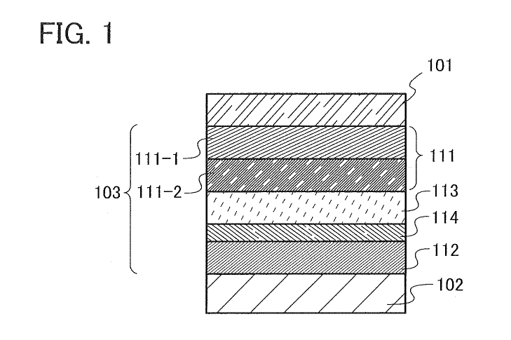

Then, a light-emitting element of one embodiment of the present invention is described in detail with reference to drawings. FIG. 1 illustrates the light-emitting element of one embodiment of the present invention. The light-emitting element of one embodiment of the present invention includes an anode 101, a cathode 102, and an EL layer 103. The EL layer 103 includes a hole injection/transport layer 111 and a light-emitting layer 113. Note that the EL layer 103 may include a layer having a different function, such as an electron injection/transport layer 112 or a buffer layer 114, in addition to the hole injection/transport layer 111 and the light-emitting layer 113.

The anode 101 is preferably formed using, for example, any of metals, alloys, and electrically conductive compounds with a high work function (specifically, a work function of 4.0 eV or more) and mixtures thereof. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may be formed by application of a sol-gel method or the like. In an example of the formation method, indium oxide-zinc oxide is deposited by a sputtering method using a target obtained by adding zinc oxide to indium oxide at greater than or equal to 1 wt % and less than or equal to 20 wt %. Furthermore, indium oxide containing tungsten oxide and zinc oxide (IWZO) can be deposited by a sputtering method using a target in which tungsten oxide and zinc oxide are added to indium oxide at greater than or equal to 0.5 wt % and less than or equal to 5 wt % and greater than or equal to 0.1 wt % and less than or equal to 1 wt %, respectively. Other examples include gold (Au), platinum (Pt), nickel (Ni), tungsten (W), chromium (Cr), molybdenum (Mo), iron (Fe), cobalt (Co), copper (Cu), palladium (Pd), aluminum (Al), and nitrides of metal materials (e.g., titanium nitride). Graphene can also be used. In one embodiment of the present invention, the hole injection/transport layer 111 contains a first substance and a second substance; thus, an electrode material other than the above can be selected regardless of the work function.

The hole injection/transport layer 111 is closer to the anode 101 than the light-emitting layer 113 is, and is in contact with the anode 101. The hole injection/transport layer 111 includes a hole-injection layer 111-1 and may include a hole-transport layer 111-2. The hole-injection layer 111-1 is in contact with the anode 101. In the case where the hole-transport layer 111-2 is included, the hole-transport layer 111-2 is provided between the hole-injection layer 111-1 and the light-emitting layer 113.

The hole-injection layer 111-1 contains the first substance which is an organic compound having a hole-transport property and the second substance having an electron acceptor property with respect to the first substance. The first substance and the second substance are preferably mixed to form a composite material. The composite material can be formed by co-evaporation of the first substance and the second substance.

In the hole-injection layer 111-1, the second substance extracts an electron from the first substance at least when an electric field is applied (an electric field is not necessary depending on the combination of the first substance and the second substance); as a result, a hole is generated in the first substance. By the electric field, the electron flows to the anode 101 and the hole is injected into the light-emitting layer 113. In the case where a hole from the anode 101 is injected into the EL layer 103 containing an organic compound, a barrier due to a large difference between the work function of the anode 101 and the HOMO level of the organic compound in contact with the anode 101 arises, increasing driving voltage. However, in the case where an electron is extracted from the first substance and flows from the hole-injection layer 111-1 to the anode 101 as in this embodiment, an increase in driving voltage is suppressed, leading to easy hole injection into the EL layer, specifically into the light-emitting layer.

Note that a stacked-layer structure of the first substance and the second substance enables the second substance to extract an electron from the first substance at the interface. However, such a structure is not preferable because the resulting device might include excessive electrons when the hole mobility of a layer containing the first substance is low. Space charge limited current is dominant in current that flows in the layer containing the first substance, which becomes a significant problem specifically when the layer is made thick. Meanwhile, in the case where the first substance and the second substance are mixed to form a composite material as described above, holes are generated everywhere in the hole-injection layer 111-1, leading to high hole density in the bulk (layer) and high hole conductivity. Consequently, the first substance and the second substance are preferably mixed to form a composite material.

In addition, the use of a material having a deep HOMO level as the first substance can further facilitate hole injection into the light-emitting layer 113. Specifically, the HOMO level of the first substance is preferably −7.0 eV to −5.7 eV and further preferably −7.0 eV to −6.0 eV. Note that the first substance formed using a substance having a hole-transport property preferably has a hole mobility greater than or equal to 10⁻⁶ cm²/Vs.

Examples of the material of the first substance include aromatic amines such as N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B); carbazole derivatives such as 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene; and aromatic hydrocarbons such as 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, pentacene, coronene, rubrene, perylene, and 2,5,8,11-tetra(tert-butyl)perylene. The aromatic hydrocarbon may have a vinyl group. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA).

A high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: poly-TPD) can also be used.

It is particularly preferable to select a material having a hole-transport property and a deep HOMO level as the first substance as described above because a quantum dot has a deep HOMO level. As such a substance, a heterocyclic compound having a dibenzothiophene skeleton or a dibenzofuran skeleton; an aromatic hydrocarbon having one or more of a carbazole skeleton, a fluorene skeleton, a naphthalene skeleton, a phenanthrene skeleton, and a triphenylene skeleton; or an organic compound including 4 to 25 benzene rings is preferable. Note that all rings included in the organic compound are benzene rings. Note that the above organic compound does not preferably have an arylamine skeleton because an arylamine skeleton in the molecular structure might result in a shallow HOMO level. A compound having a carbazole skeleton can be easily designed to have a HOMO level lower than or equal to −5.7 eV but cannot be designed to have a HOMO level lower than or equal to −6.0 eV easily because the HOMO level of 9-phenyl-9H-carbazol, which is one of the simplest carbazole compound, is −5.88 eV when measured by cyclic voltammetry. Meanwhile, it is more suitable to use a heterocyclic compound having a dibenzothiophene skeleton or a dibenzofuran skeleton; an aromatic hydrocarbon having one or more of a fluorene skeleton, a naphthalene skeleton, a phenanthrene skeleton, and a triphenylene skeleton; or an organic compound in which 4 to 25 benzene rings are included and all rings therein are benzene rings because the HOMO level thereof can be easily designed to be lower than or equal to −6.0 eV. It is needless to say that the above compounds do not preferably have an arylamine skeleton in their molecular structures.

As the heterocyclic compound having a dibenzothiophene skeleton or a dibenzofuran skeleton, an organic compound represented by the following general formula (G1) is suitable.

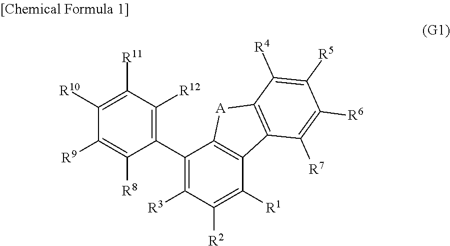

In the formula, A represents oxygen or sulfur; each of R¹ to R⁷ independently represents hydrogen, an alkyl group having 1 to 4 carbon atoms, or an aryl group having 6 to 25 carbon atoms forming a ring; and each of R⁸ to R¹² independently represents hydrogen, a substituted or unsubstituted phenyl group, a substituted or unsubstituted naphthyl group, a substituted or unsubstituted phenanthryl group, a substituted or unsubstituted triphenylenyl group, a substituted or unsubstituted fluorenyl group, a substituted or unsubstituted dibenzothiophenyl group, or a substituted or unsubstituted dibenzofuranyl group. Note that at least one of R⁸ to R¹² represents a substituted or unsubstituted phenyl group, a substituted or unsubstituted naphthyl group, a substituted or unsubstituted phenanthryl group, a substituted or unsubstituted triphenylenyl group, a substituted or unsubstituted fluorenyl group, a substituted or unsubstituted dibenzothiophenyl group, or a substituted or unsubstituted dibenzofuranyl group.

As a heterocyclic compound having a carbazole skeleton, an organic compound represented by the following general formula (G2) is suitable.

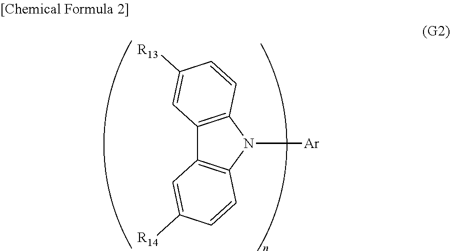

In the formula, Ar represents an aromatic hydrocarbon group having 6 to 42 carbon atoms; n represents a natural number of 1 to 3; and each of R¹⁴ and R¹⁵ represents hydrogen, an alkyl group having 1 to 4 carbon atoms, or an aryl group having 6 to 12 carbon atoms.

As a heterocyclic compound having fluorene skeleton, an organic compound represented by the following general formula (G3), which has a molecular weight of greater than or equal to 400 and less than or equal to 2000, is suitable.

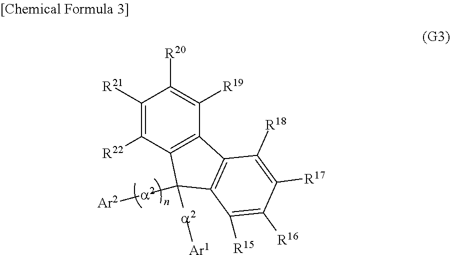

Note that in the formula, each of α¹ and α² independently represents a substituted or unsubstituted phenylene group or a substituted or unsubstituted biphenyldiyl group; n is 0 or 1; each of Ar¹ and Ar² represents a substituted or unsubstituted aryl group; and each of R¹⁵ to R²² independently represents hydrogen, an alkyl group having 1 to 6 carbon atoms, a substituted or unsubstituted phenyl group, a substituted or unsubstituted biphenyl group, a substituted or unsubstituted naphthyl group, or a substituted or unsubstituted phenanthryl group.

As a heterocyclic compound having a phenanthrene skeleton, an organic compound represented by the following general formula (G4) is suitable.

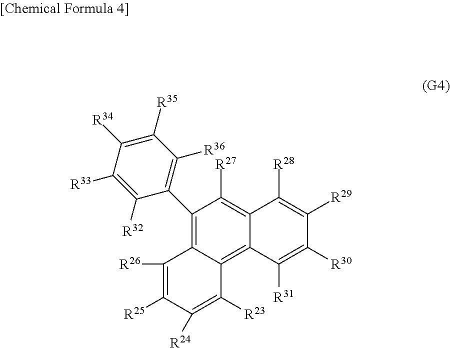

In the formula, each of R²³ to R³¹ independently represents hydrogen, an alkyl group having 1 to 4 carbon atoms, or an aryl group having 6 to 25 carbon atoms forming a ring; and each of R³² to R³⁶ independently represents hydrogen, an alkyl group having 1 to 6 carbon atoms, a substituted or unsubstituted phenyl group, a substituted or unsubstituted naphthyl group, a substituted or unsubstituted phenanthryl group, or a substituted or unsubstituted triphenylenyl group. Note that at least one of R³² to R³⁶ represents a substituted or unsubstituted phenyl group, a substituted or unsubstituted naphthyl group, a substituted or unsubstituted phenanthryl group, or a substituted or unsubstituted triphenylenyl group.

As a heterocyclic compound having a naphthalene skeleton, an organic compound represented by the following general formula (G5) or (G6) is suitable.

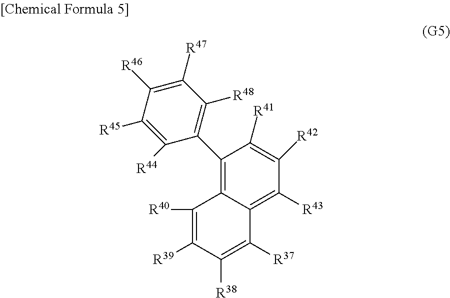

In the formula, each of R³⁷ to R⁴³ independently represents hydrogen, an alkyl group having 1 to 4 carbon atoms, or an aryl group having 6 to 25 carbon atoms forming a ring; and each of R⁴⁴ to R⁴⁸ independently represents hydrogen, an alkyl group having 1 to 6 carbon atoms, a substituted or unsubstituted phenyl group, a substituted or unsubstituted naphthyl group, a substituted or unsubstituted phenanthryl group, or a substituted or unsubstituted triphenylenyl group. Note that at least one of R⁴⁴ to R⁴⁸ represents a substituted or unsubstituted phenyl group, a substituted or unsubstituted naphthyl group, a substituted or unsubstituted phenanthryl group, or a substituted or unsubstituted triphenylenyl group.

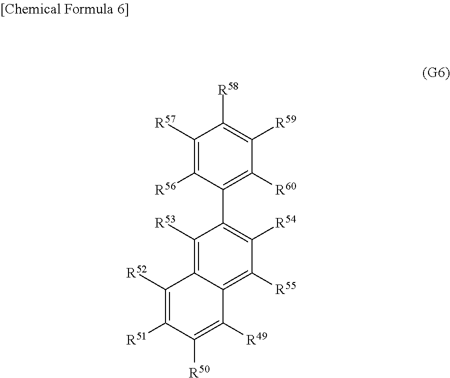

In the formula, each of R⁴⁹ to R⁵⁵ independently represents hydrogen, an alkyl group having 1 to 4 carbon atoms, or an aryl group having 6 to 25 carbon atoms forming a ring; and each of R⁵⁶ to R⁶⁰ independently represents hydrogen, an alkyl group having 1 to 6 carbon atoms, a substituted or unsubstituted phenyl group, a substituted or unsubstituted naphthyl group, a substituted or unsubstituted phenanthryl group, or a substituted or unsubstituted triphenylenyl group. Note that at least one of R⁵⁶ to R⁶⁰ represents a substituted or unsubstituted phenyl group, a substituted or unsubstituted naphthyl group, a substituted or unsubstituted phenanthryl group, or a substituted or unsubstituted triphenylenyl group.

As a heterocyclic compound having a triphenylene skeleton, an organic compound represented by the following general formula (G7) is suitable.

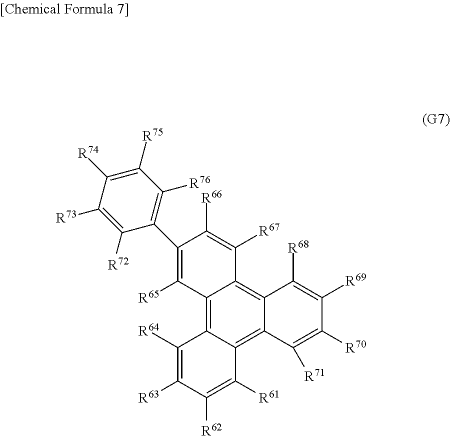

In the formula, each of R⁶¹ to R⁷¹ independently represents hydrogen, an alkyl group having 1 to 4 carbon atoms, or an aryl group having 6 to 25 carbon atoms faulting a ring; and each of R⁷² to R⁷⁶ independently represents hydrogen, an alkyl group having 1 to 6 carbon atoms, a substituted or unsubstituted phenyl group, a substituted or unsubstituted naphthyl group, a substituted or unsubstituted phenanthryl group, or a substituted or unsubstituted triphenylenyl group. Note that at least one of R⁷² to R⁷⁶ represents a substituted or unsubstituted phenyl group, a substituted or unsubstituted naphthyl group, a substituted or unsubstituted phenanthryl group, or a substituted or unsubstituted triphenylenyl group.

As the second substance, a material having an electron acceptor property with respect to the first substance that has a hole-transport property is used. Typical examples of the material include a transition metal oxide, an oxide of a metal belonging to any of Groups 4 to 8 in the periodic table, and an organic compound having an electron-withdrawing group (a halogen group or a cyano group). It is suitable to use a transition metal oxide or an oxide of a metal belonging to any of Groups 4 to 8 in the periodic table as the second substance because such an oxide has an electron acceptor property (or can extract an electron at least when an electric field is applied) also with respect to a substance having a hole-transport property whose HOMO level is lower (deeper) than −5.4 eV. Such an oxide can be regarded to have a very effective property for a QLED element because it can actually have an electron acceptor property even with respect to a substance having a hole-transport property whose HOMO level is lower than or equal to −5.7 eV, especially lower than or equal to −6.0 eV.

Examples of the organic compound having an electron-withdrawing group (a halogen group or a cyano group) include 7,7,8,8-tetracyano-2,3,5,6-tetrafluoroquinodimethane (abbreviation: F₄-TCNQ), chloranil, and 2,3,6,7,10,11-hexacyano-1,4,5,8,9,12-hexaazatriphenylene (abbreviation: HAT-CN). A compound in which electron-withdrawing groups are bonded to a condensed aromatic ring having a plurality of hetero atoms, like HAT-CN, is particularly preferable because it is thermally stable.

As the transition metal oxide or the oxide of a metal belonging to any of Groups 4 to 8 in the periodic table, a vanadium oxide, a niobium oxide, a tantalum oxide, a chromium oxide, a molybdenum oxide, a tungsten oxide, a manganese oxide, a rhenium oxide, a titanium oxide, a ruthenium oxide, a zirconium oxide, a hafnium oxide, or a silver oxide is preferable because of its high electron acceptor property. A molybdenum oxide is particularly preferable because of its high stability in the air, low hygroscopicity, and high handiness.

In the case of providing the hole-transport layer 111-2, an organic compound having a hole-transport property can be used for the hole-transport layer 111-2. The organic compound having a hole-transport property preferably has a high hole-transport property and has a hole mobility greater than or equal to 10⁻⁶ cm²/Vs. Specific examples of the organic compound include the substances having a hole-transport property given as organic compounds that can be used for the first substance in the hole-injection layer 111-1; a compound having an aromatic amine skeleton, such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton such as 1,3,5-tri-(4-dibenzothiophenyl)-benzene (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, a compound having an aromatic amine skeleton and a compound having a carbazole skeleton are preferable because these compounds are highly reliable and have high hole-transport properties and contribute to a reduction in drive voltage.

Note that the HOMO level of a substance for forming the hole-transport layer 111-2 is preferably lower than or equal to the HOMO level of the first substance and higher than or equal to the HOMO level of a quantum dot. It is further preferable that the substance for forming the hole-transport layer 111-2 be the first substance.

Examples of a material of a quantum dot used as a light-emitting substance in the light-emitting layer 113 include a Group 14 element in the periodic table, a Group 15 element in the periodic table, a Group 16 element in the periodic table, a compound of a plurality of Group 14 elements in the periodic table, a compound of an element belonging to any of Groups 4 to 14 in the periodic table and a Group 16 element in the periodic table, a compound of a Group 2 element in the periodic table and a Group 16 element in the periodic table, a compound of a Group 13 element in the periodic table and a Group 15 element in the periodic table, a compound of a Group 13 element in the periodic table and a Group 17 element in the periodic table, a compound of a Group 14 element in the periodic table and a Group 15 element in the periodic table, a compound of a Group 11 element in the periodic table and a Group 17 element in the periodic table, iron oxides, titanium oxides, spinel chalcogenides, and semiconductor clusters.

Specific examples include, but are not limited to, cadmium selenide (CdSe); cadmium sulfide (CdS); cadmium telluride (CdTe); zinc selenide (ZnSe); zinc oxide (ZnO); zinc sulfide (ZnS); zinc telluride (ZnTe); mercury sulfide (HgS); mercury selenide (HgSe); mercury telluride (HgTe); indium arsenide (InAs); indium phosphide (InP); gallium arsenide (GaAs); gallium phosphide (GaP); indium nitride (InN); gallium nitride (GaN); indium antimonide (InSb); gallium antimonide (GaSb); aluminum phosphide (AlP); aluminum arsenide (AlAs); aluminum antimonide (AlSb); lead(II) selenide (PbSe); lead(II) telluride (PbTe); lead(II) sulfide (PbS); indium selenide (In₂Se₃); indium telluride (In₂Te₃); indium sulfide (In₂S₃); gallium selenide (Ga₂Se₃); arsenic(III) sulfide (As₂S₃); arsenic(III) selenide (As₂Se₃); arsenic(III) telluride (As₂Te₃); antimony(III) sulfide (Sb₂S₃); antimony(III) selenide (Sb₂Se₃); antimony(III) telluride (Sb₂Te₃); bismuth(III) sulfide (Bi₂S₃); bismuth(III) selenide (Bi₂Se₃); bismuth(III) telluride (Bi₂Te₃); silicon (Si); silicon carbide (SiC); germanium (Ge); tin (Sn); selenium (Se); tellurium (Te); boron (B); carbon (C); phosphorus (P); boron nitride (BN); boron phosphide (BP); boron arsenide (BAs); aluminum nitride (AlN); aluminum sulfide (Al₂S₃); barium sulfide (BaS); barium selenide (BaSe); barium telluride (BaTe); calcium sulfide (CaS); calcium selenide (CaSe); calcium telluride (CaTe); beryllium sulfide (BeS); beryllium selenide (BeSe); beryllium telluride (BeTe); magnesium sulfide (MgS); magnesium selenide (MgSe); germanium sulfide (GeS); germanium selenide (GeSe); germanium telluride (GeTe); tin(IV) sulfide (SnS₂); tin(II) sulfide (SnS); tin(II) selenide (SnSe); tin(II) telluride (SnTe); lead(II) oxide (PbO); copper(I) fluoride (CuF); copper(I) chloride (CuCI); copper(I) bromide (CuBr); copper(I) iodide (CuI); copper(I) oxide (Cu₂O); copper(I) selenide (Cu₂Se); nickel(II) oxide (NiO); cobalt(II) oxide (CoO); cobalt(II) sulfide (CoS); triiron tetraoxide (Fe₃O₄); iron(II) sulfide (FeS); manganese(II) oxide (MnO); molybdenum(IV) sulfide (MoS₂); vanadium(II) oxide (VO); vanadium(IV) oxide (VO₂); tungsten(IV) oxide (WO₂); tantalum(V) oxide (Ta₂O₅); titanium oxide (e.g., TiO₂, Ti₂O₅, Ti₂O₃, or Ti₅O₉); zirconium oxide (ZrO₂); silicon nitride (Si₃N₄); germanium nitride (Ge₃N₄); aluminum oxide (Al₂O₃); barium titanate (BaTiO₃); a compound of selenium, zinc, and cadmium (CdZnSe); a compound of indium, arsenic, and phosphorus (InAsP); a compound of cadmium, selenium, and sulfur (CdSeS); a compound of cadmium, selenium, and tellurium (CdSeTe); a compound of indium, gallium, and arsenic (InGaAs); a compound of indium, gallium, and selenium (InGaSe); a compound of indium, selenium, and sulfur (InSeS); a compound of copper, indium, and sulfur (e.g., CuInS₂); and combinations thereof. What is called an alloyed quantum dot, whose composition is represented by a given ratio, may be used. For example, an alloyed quantum dot represented by CdSₓSe₁₋ₓ (where x is any number between 0 and 1 inclusive) is a means effective in obtaining blue light because the emission wavelength can be changed by changing x.

As the quantum dot, any of a core-type quantum dot, a core-shell quantum dot, a core-multishell quantum dot, and the like can be used. Note that when a core is covered with a shell formed of another inorganic material having a wider band gap, the influence of defects and dangling bonds existing at the surface of a nanocrystal can be reduced. Since such a structure can significantly improve the quantum efficiency of light emission, it is preferable to use a core-shell or core-multishell quantum dot. Examples of the material of a shell include zinc sulfide (ZnS) and zinc oxide (ZnO).

Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It can also reduce reactivity and improve electrical stability. Examples of the protective agent (or the protective group) include polyoxyethylene alkyl ethers such as polyoxyethylene lauryl ether, polyoxyethylene stearyl ether, and polyoxyethylene oleyl ether; trialkylphosphines such as tripropylphosphine, tributylphosphine, trihexylphosphine, and trioctylphosphine; polyoxyethylene alkylphenyl ethers such as polyoxyethylene n-octylphenyl ether and polyoxylethylene n-nonylphenyl ether; tertiary amines such as tri(n-hexyl)amine, tri(n-octyl)amine, and tri(n-decyl)amine; organophosphorus compounds such as tripropylphosphine oxide, tributylphosphine oxide, trihexylphosphine oxide, trioctylphosphine oxide, and tridecylphosphine oxide; polyethylene glycol diesters such as polyethylene glycol dilaurate and polyethylene glycol distearate; organic nitrogen compounds such as nitrogen-containing aromatic compounds, e.g., pyridines, lutidines, collidines, and quinolones; animoalkanes such as hexylamine, octylamine, decylamine, dodecylamine, tetradecylamine, hexadecylamine, and octadecylamine; dialkylsulfides such as dibutylsulfide; dialkylsulfoxides such as dimethylsulfoxide and dibutylsulfoxide; organic sulfur compounds such as sulfur-containing aromatic compounds, e.g., thiophene; higher fatty acids such as a palmitin acid, a stearic acid, and an oleic acid; alcohols; sorbitan fatty acid esters; fatty acid modified polyesters; tertiary amine modified polyurethanes; and polyethyleneimines.

The quantum dots may be quantum rods, which are rod-like shape quantum dots. A quantum rod emits directional light polarized in the c-axis direction; thus, quantum rods can be used as a light-emitting material to obtain a light-emitting element with higher external quantum efficiency.

In most OLED elements, to improve luminous efficiency, light-emitting materials are dispersed in host materials and the host materials need to be substances having singlet excitation energy or triplet excitation energy higher than or equal to that of the light-emitting materials. In the case of using a blue phosphorescent material, it is particularly difficult to develop a host material which has triplet excitation energy higher than or equal to that of the blue phosphorescent material and which is excellent in terms of lifetime. Even when the light-emitting layer 113 is composed of quantum dots and made without a host material, the quantum dots enable luminous efficiency to be ensured; thus, a light-emitting element which is favorable in terms of lifetime can be obtained. In the case where the light-emitting layer is composed of quantum dots, the quantum dots preferably have core-shell structures (including core-multishell structures).

The light-emitting layer 113 may contain, in addition to the quantum dots, a different light-emitting material or a host material. Typical examples of the different light-emitting material include a phosphorescent substance, a fluorescent substance, and a thermally activated delayed fluorescence substance.

Examples of a material that can be used as a phosphorescent substance include tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), and tris[4-(3-biphenyl)-5-isopropyl-3-phenyl-4H-1,2,4-triazolato]iridium(III) (abbreviation: [Ir(iPrptz-3b)₃]); organometallic iridium complexes having 1H-triazole skeletons, such as tris[3-methyl-1-(2-methylphenyl)-5-phenyl-1H-1,2,4-triazolato]iridium(III) (abbreviation: [Ir(Mptzl-mp)₃]) and tris(1-methyl-5-phenyl-3-propyl-1H-1,2,4-triazolato)iridium(III) (abbreviation: [Ir(Prptzl-Me)₃]); organometallic iridium complexes having imidazole skeletons, such as fac-tris[(1-2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); and organometallic iridium complexes in which aphenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac). These are compounds emitting blue phosphorescence and have an emission peak at 440 nm to 520 nm.

Other examples include organometallic iridium complexes having pyrimidine skeletons, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having pyrazine skeletons, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having pyridine skeletons, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), and bis(2-phenylquinolinato-N,C^{2′})iridium(III) acetylacetonate (abbreviation: [Ir(pq)₂(acac)]); and rare earth metal complexes such as tris(acetylacetonato)(monophenanthroline)terbium(III) (abbreviation: [Tb(acac)₃(Phen)]). These are mainly compounds emitting green phosphorescence and have an emission peak at 500 nm to 600 nm. Note that organometallic iridium complexes having pyrimidine skeletons have distinctively high reliability and luminous efficiency and thus are especially preferable.

Other examples include organometallic iridium complexes having pyrimidine skeletons, such as (diisobutyrylmethanato)bis[4,6-bis(3-methylphenyl)pyrimidinato]iridium (III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), (dipivaloylmethanato)bis[4,6-di(naphthalen-1-yl)pyrimidinato]iridium(III) (abbreviation: [Ir(d1npm)₂(dpm)]); organometallic iridium complexes having pyrazine skeletons, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having pyridine skeletons, such as tris(1-phenylisoquinolinato-N,C^{2′})iridium(III) (abbreviation: [Ir(piq)₃]) and bis(1-phenylisoquinolinato-N,C^{2′})iridium(III) acetylacetonate (abbreviation: [Ir(piq)₂(acac)]); platinum complexes such as 2,3,7,8,12,13,17,18-octaethyl-21H,23H-porphyrin platinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These are compounds emitting red phosphorescence and have an emission peak at 600 nm to 700 nm. Furthermore, organometallic iridium complexes having pyrazine skeletons can provide red light emission with favorable chromaticity.

As well as the above phosphorescent compounds, any of a variety of phosphorescent materials may be selected and used.

Instead of the phosphorescent substance, a thermally activated delayed fluorescence substance (TADF material) may be used. Examples of the TADF material include a fullerene, a derivative thereof, an acridine derivative such as proflavine, and eosin. Furthermore, a metal-containing porphyrin, such as a porphyrin containing magnesium (Mg), zinc (Zn), cadmium (Cd), tin (Sn), platinum (Pt), indium (In), or palladium (Pd) can be used. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP) represented by the following structural formulae.

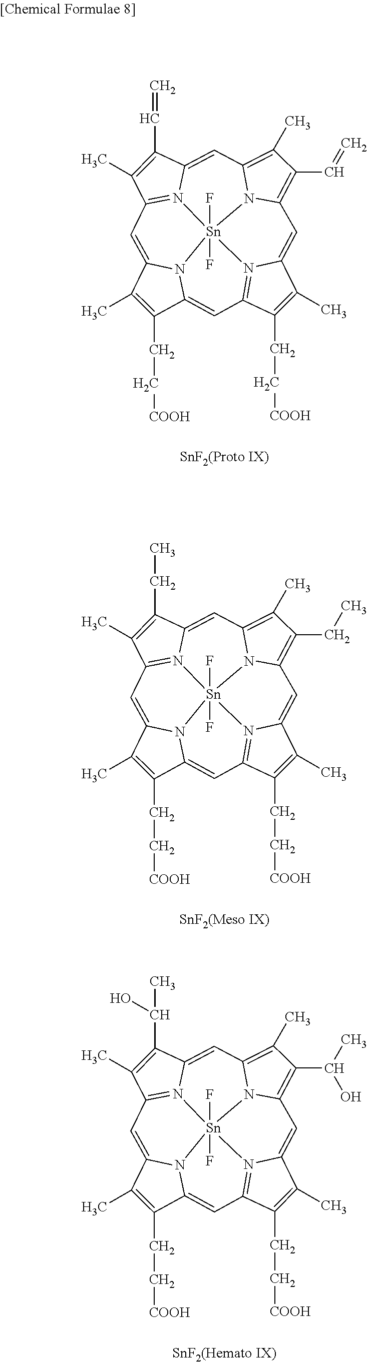

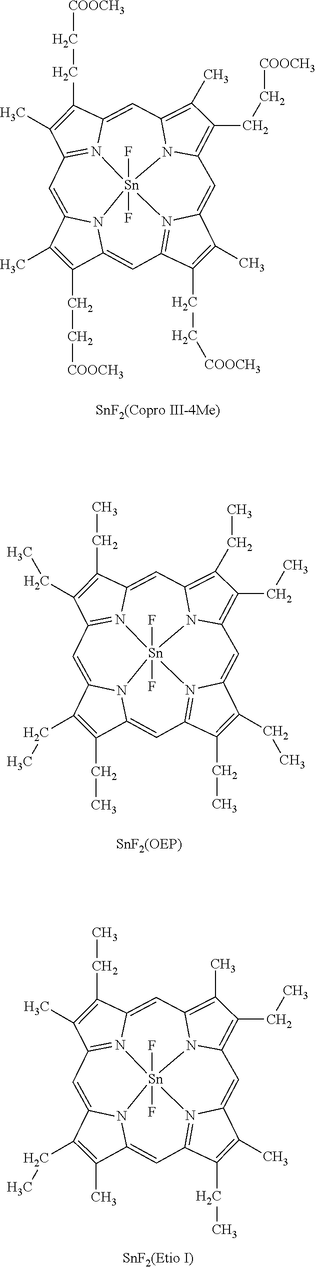

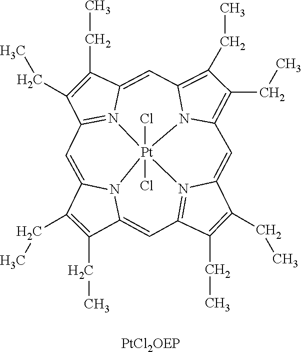

Alternatively, a heterocyclic compound having both a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) shown in the following structural formulae, can be used. The heterocyclic compound is preferable because of having a high electron-transport and hole-transport properties owing to a π-electron rich heteroaromatic ring and a π-electron deficient heteroaromatic ring. Note that a substance in which the π-electron rich heteroaromatic ring is directly bonded to the π-electron deficient heteroaromatic ring is particularly preferable because the donor property of the π-electron rich heteroaromatic ring and the acceptor property of the π-electron deficient heteroaromatic ring are both increased, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring.

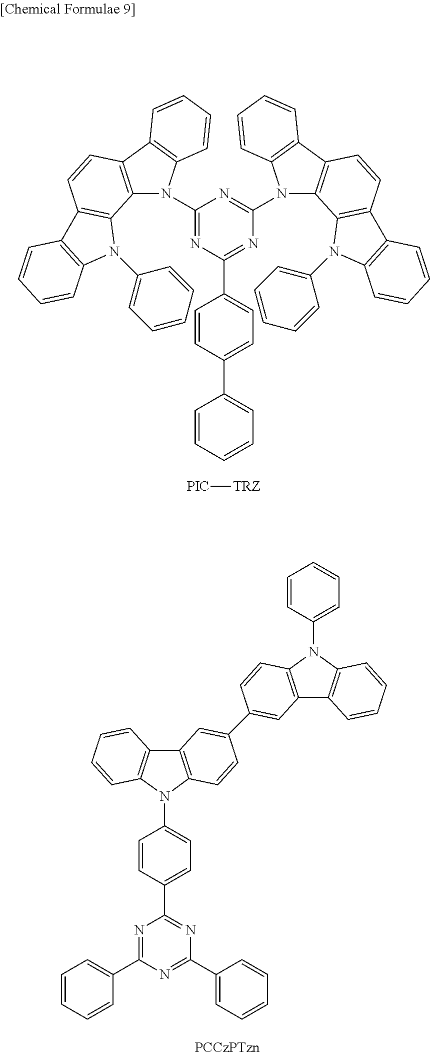

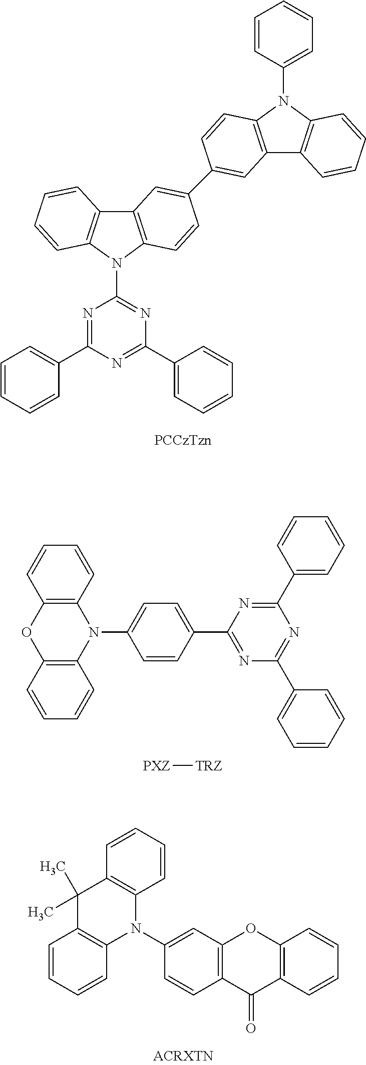

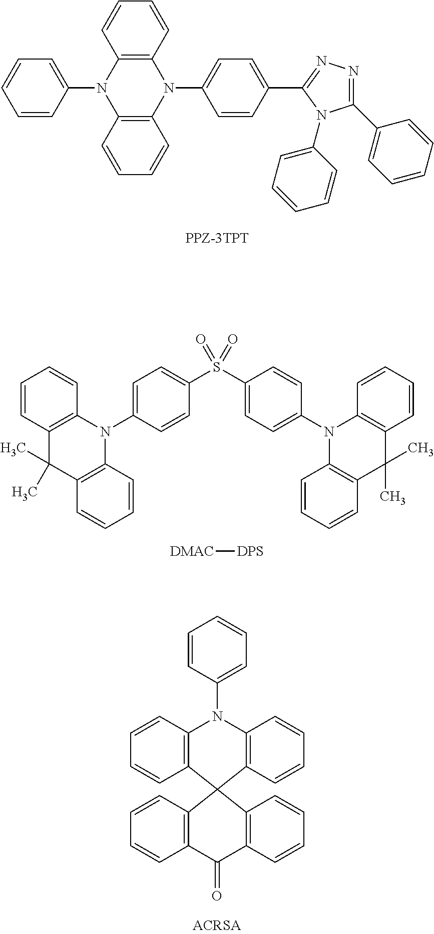

As the fluorescent substance, any of the following substances can be used, for example. Fluorescent substances other than those given below can also be used. Examples of the fluorescent substance are 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 2,8-di-tert-butyl-5,11-bis(4-tert-butylphenyl)-6,12-diphenyltetracene (abbreviation: TBRb), 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), and the like. Condensed aromatic diamine compounds typified by pyrenediamine compounds such as 1,6FLPAPm and 1,6mMemFLPAPm are preferable because of their high hole-trapping properties, high luminous efficiency, and high reliability.

A variety of carrier-transport materials can be used as the host material. As the carrier-transport material, any of substances having a hole-transport property and substances having an electron-transport property listed below and the like can be used. It is needless to say that it is possible to use a material having a hole-transport property, a material having an electron-transport property, or a bipolar material other than the substances listed below.

As the material having a hole-transport property, any of the substances given as materials for fainting the hole-transport layer 111-2 can be used.

Examples of the material with an electron-transport property are a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); a heterocyclic compound having a polyazole skeleton such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); a heterocyclic compound having a diazine skeleton such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), or 4,6-bis[3-(4-dibenzothienyl)phenyl]pyrimidine (abbreviation: 4,6mDBTP2Pm-II); and a heterocyclic compound having a pyridine skeleton such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB). Among the above materials, a heterocyclic compound having a diazine skeleton and a heterocyclic compound having a pyridine skeleton have high reliability and are thus preferable. Specifically, a heterocyclic compound having a diazine (pyrimidine or pyrazine) skeleton has a high electron-transport property to contribute to a reduction in drive voltage.

Note that the host material may be a mixture of a plurality of kinds of substances, and in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The ratio of the content of the material having a hole-transport property to the content of the material having an electron-transport property may be 1:9 to 9:1.

An exciplex may be formed by these mixed materials. It is preferable that the combination of these materials be selected so as to form an exciplex that exhibits light emission whose wavelength overlaps with a wavelength of a lowest-energy-side absorption band of the light-emitting material, in which case energy is transferred smoothly, light emission can be obtained efficiently, and the drive voltage is reduced.

In the case of using quantum dots as the light-emitting material in the light-emitting layer 113, the thickness of the light-emitting layer is set to 3 nm to 100 nm, preferably 10 nm to 100 nm, and the light-emitting layer is made to contain 1 volume % to 100 volume % of the quantum dots. Note that it is preferable that the light-emitting layer be composed of the quantum dots. To form a light-emitting layer in which the quantum dots are dispersed as light-emitting materials in host materials, the quantum dots may be dispersed in the host materials, or the host materials and the quantum dots may be dissolved or dispersed in an appropriate liquid medium, and then a wet process (e.g., a spin coating method, a casting method, a die coating method, blade coating method, a roll coating method, an ink-jet method, a printing method, a spray coating method, a curtain coating method, or a Langmuir-Blodgett method) may be employed. For a light-emitting layer containing a phosphorescent substance, a vacuum evaporation method, as well as the wet process, can be suitably employed.

An example of the liquid medium used for the wet process is an organic solvent of ketones such as methyl ethyl ketone and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; dimethylformamide (DMF); dimethyl sulfoxide (DMSO); or the like.

The electron injection/transport layer 112 has functions of injecting an electron into the EL layer and transporting an electron. The electron injection/transport layer 112 includes an electron-transport layer and may include an electron-injection layer. The electron injection/transport layer contains a substance having an electron-transport property. As the substance having an electron-transport property, it is possible to use any of the above-listed substances having an electron-transport property that can be used as a host material can be used. An n-type compound semiconductor may also be used, and an oxide such as titanium oxide (TiO₂), zinc oxide (ZnO), silicon oxide (SiO₂), tin oxide (SnO₂), tungsten oxide (WO₃), tantalum oxide (Ta₂O₃), barium titanate (BaTiO₃), barium zirconate (BaZrO₃), zirconium oxide (ZrO₂), hafnium oxide (HfO₂), aluminum oxide (Al₂O₃), yttrium oxide (Y₂O₃), or zirconium silicate (ZrSiO₄); a nitride such as silicon nitride (Si₃N₄); cadmium sulfide (CdS); zinc selenide (ZnSe); or zinc sulfide (ZnS) can be used, for example. An n-type semiconductor is particularly preferable because its valence band maximum is close to that of a quantum dot, which results in an effect of reducing driving voltage.

In the case of providing the electron-injection layer, an alkali metal, an alkaline earth metal, or a compound thereof such as lithium fluoride (LiF), cesium fluoride (CsF), or calcium fluoride (CaF₂) is provided in contact with the cathode 102. Alternatively, a layer that contains a substance having an electron-transport property and an alkali metal, an alkaline earth metal, a compound thereof, or an electride may be used. Examples of the electride include a substance in which electrons are added at high concentration to a calcium oxide-aluminum oxide. Note that the electron-injection layer is unnecessary for a QLED element because an electron can be injected relatively easily. In such a structure, an alkali metal or an alkaline earth metal that is sensitive to an atmospheric component is not used, leading to a highly reliable light-emitting element.

The buffer layer 114 may be provided between the electron injection/transport layer 112 and the light-emitting layer 113. The buffer layer 114 can prevent an interaction between the electron injection/transport layer 112 and the light-emitting layer 113, leading to a light-emitting element with high luminous efficiency.

Examples of a substance contained in the cathode 102 include an element belonging to Group 1 or 2 in the periodic table such as an alkali metal (e.g., lithium (Li) or cesium (Cs)), magnesium (Mg), calcium (Ca), or strontium (Sr) or an alloy containing the element (MgAg or AlLi); a rare earth metal such as europium (Eu) or ytterbium (Yb) or an alloy containing the metal; ITO; indium oxide-tin oxide containing silicon or silicon oxide; indium oxide-zinc oxide; and indium oxide containing tungsten oxide and zinc oxide (IWZO). Any of a variety of conductive materials such as aluminum (Al), silver (Ag), indium tin oxide (ITO), and indium oxide-tin oxide containing silicon or silicon oxide can be used for the cathode 102. A dry method such as a vacuum evaporation method or a sputtering method, an ink-jet method, a spin coating method, or the like can be used for depositing these conductive materials. Alternatively, a wet method using a sol-gel method, or a wet method using a paste of a metal material can be used.

Any of a variety of methods can be employed for forming the EL layer 103 regardless of whether it is a dry method or a wet method. For example, a vacuum evaporation method or a wet process (e.g., a spin coating method, a casting method, a die coating method, a blade coating method, a roll coating method, an ink-jet method, a printing method (e.g., a gravure printing method, an offset printing method, or a screen printing method), a spray coating method, a curtain coating method, or a Langmuir-Blodgett method) can be used. It is particularly preferable that the light-emitting layer 113 containing quantum dots or the electron injection/transport layer 112 containing an n-type semiconductor be formed by a wet method.

Different methods may be used to form the electrodes or the layers described above.

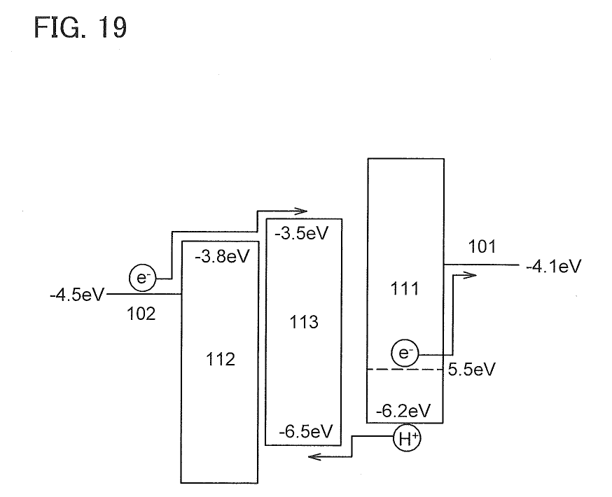

FIG. 19 illustrates an example of an energy band diagram of a light-emitting element of one embodiment of the present invention having the above structure. The light-emitting element includes the anode 101, the cathode 102, the hole injection/transport layer 111, the electron injection/transport layer 112, and the light-emitting layer 113. In the light-emitting element, aluminum, ITO, ZnO, and a composite material of DBT3P-II and a molybdenum oxide are used for the anode 101, the cathode 102, the electron injection/transport layer 112, and the hole injection/transport layer 111, respectively. The light-emitting element is assumed to be what is called an inversely stacked element that is formed from the cathode 102 side.

In the light-emitting element of one embodiment of the present invention, an electron injected from the cathode 102 is smoothly transferred to the light-emitting layer 113 because the difference between the valence band maximum of ZnO, which is the electron injection/transport layer 112, and the LUMO level of the light-emitting layer 113 containing quantum dots is small as illustrated in FIG. 19. Furthermore, a pair electron-hole is generated in the hole injection/transport layer 111 when voltage is applied and the molybdenum oxide extracts an electron from DBT3P-II, leaving a hole in DBT3P-II. The electron flows to the anode 101, and the hole is smoothly injected into the light-emitting layer 113 because the HOMO level of DBT3P-II is deep and proximity to the HOMO level of the light-emitting layer 113 containing the quantum dots. Since a hole and an electron are smoothly injected into the light-emitting layer 113, the light-emitting element of one embodiment of the present invention can have low driving voltage and an excellent carrier balance.

The structure of the layers provided between the anode 101 and the cathode 102 is not limited to the above-described structure. Preferably, a light-emitting region where holes and electrons recombine is positioned away from the anode 101 and the cathode 102 so that quenching due to the proximity of the light-emitting region and a metal used for electrodes and carrier-injection layers can be prevented.

Furthermore, in order that transfer of energy from an exciton generated in the light-emitting layer can be suppressed, preferably, the hole-transport layer and the electron-transport layer which are in contact with the light-emitting layer 113, particularly a carrier-transport layer closer to the recombination region in the light-emitting layer 113, are formed using a substance having a wider band gap than the light-emitting substance of the light-emitting layer or the emission center substance included in the light-emitting layer.

### Embodiment 2

In this embodiment, a light-emitting device including the light-emitting element described in Embodiment 1 will be described.

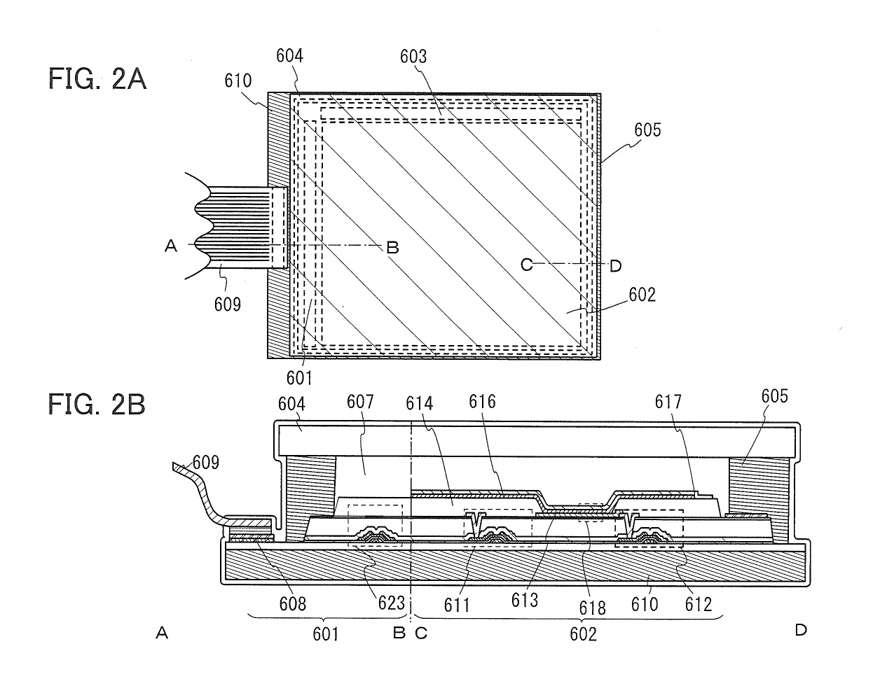

In this embodiment, the light-emitting device manufactured using the light-emitting element described in Embodiment 1 is described with reference to FIGS. 2A and 2B. Note that FIG. 2A is a top view of the light-emitting device and FIG. 2B is a cross-sectional view taken along lines A-B and C-D in FIG. 2A. This light-emitting device includes a driver circuit portion (source line driver circuit) 601, a pixel portion 602, and a driver circuit portion (gate line driver circuit) 603, which are to control light emission of a light-emitting element and illustrated with dotted lines. Reference numeral 604 denotes a sealing substrate; 605, a sealing material; and 607, a space surrounded by the sealing material 605.

Reference numeral 608 denotes a lead wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The light-emitting device in the present specification includes, in its category, not only the light-emitting device itself but also the light-emitting device provided with the FPC or the PWB.

Next, a cross-sectional structure will be described with reference to FIG. 2B. The driver circuit portions and the pixel portion are formed over an element substrate 610; FIG. 2B illustrates the source line driver circuit 601, which is a driver circuit portion, and one pixel in the pixel portion 602.

The element substrate 610 may be a substrate containing glass, quartz, an organic resin, a metal, an alloy, or a semiconductor or a plastic substrate formed of fiber reinforced plastic (FRP), poly(vinyl fluoride) (PVF), polyester, or acrylic.

There is no particular limitation on the structure of transistors used in pixels and driver circuits. For example, inverted staggered transistors may be used, or staggered transistors may be used. Furthermore, top-gate transistors or bottom-gate transistors may be used. There is no particular limitation on a semiconductor material used for the transistors, and silicon, germanium, silicon carbide, gallium nitride, or the like can be used, for example. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable that a semiconductor having crystallinity be used, in which case deterioration of the transistor characteristics can be suppressed.

Here, an oxide semiconductor is preferably used for semiconductor devices such as the transistors provided in the pixels and driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics of the transistor, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the driver circuit portion 601. In addition, the driver circuit may be formed with any of a variety of circuits such as a CMOS circuit, a PMOS circuit, or an NMOS circuit. Although a driver integrated type in which the driver circuit is formed over the substrate described in this embodiment, the driver circuit is not necessarily formed over the substrate, and the driver circuit can be formed outside, not over the substrate.

The pixel portion 602 includes a plurality of pixels including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

Note that to cover an end portion of the first electrode 613, an insulator 614, for which a positive photosensitive acrylic resin film is used here, is formed.

In order to improve coverage with an EL layer or the like which is formed later, the insulator 614 is formed to have a curved surface with curvature at its upper or lower end portion. For example, in the case where positive photosensitive acrylic is used as a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An EL layer 616 and a second electrode 617 are forming over the first electrode 613. Here, as a material used for the first electrode 613 functioning as an anode, a material having a high work function is preferably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance, favorable ohmic contact, and a function as an anode.

The EL layer 616 is formed by any of a variety of methods such as an evaporation method using an evaporation mask and a wet method, e.g., an ink-jet method or a spin coating method. The EL layer 616 has the structure described in Embodiment 1. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, and Ca, or an alloy or a compound thereof, such as MgAg, MgIn, and AlLi) is preferably used. In the case where light generated in the EL layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting element is formed with the first electrode 613, the EL layer 616, and the second electrode 617. The light-emitting element corresponds to the light-emitting element described in Embodiment 1. In the light-emitting device of this embodiment, the pixel portion, which includes a plurality of light-emitting elements, may include both the light-emitting element described in Embodiment 1 and a light-emitting element having a different structure.

The sealing substrate 604 is attached to the element substrate 610 with the sealing material 605, so that a light-emitting element 618 is provided in the space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a recessed portion and a drying agent be provided in the recessed portion, in which case deterioration due to influence of moisture can be suppressed.

An epoxy-based resin or glass frit is preferably used for the sealing material 605. It is preferable that such a material not be permeable to moisture or oxygen as much as possible. As the sealing substrate 604, a glass substrate, a quartz substrate, or a plastic substrate formed of fiber reinforced plastic (FRP), poly(vinyl fluoride) (PVF), polyester, and acrylic can be used.

Although not illustrated in FIGS. 2A and 2B, a protective film may be provided over the second electrode. As the protective film, an organic resin film or an inorganic insulating film may be formed. The protective film may be forming so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material through which an impurity such as water does not permeate easily. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of the light-emitting device.

As described above, the light-emitting device manufactured using the light-emitting element described in Embodiment 1 can be obtained.

The light-emitting device in this embodiment is manufactured using the light-emitting element described in Embodiment 1 and thus can have favorable characteristics. Specifically, since the light-emitting element described in Embodiment 1 has a long lifetime, the light-emitting device can have high reliability. Since the light-emitting device using the light-emitting element described in Embodiment 1 has high luminous efficiency, the light-emitting device can achieve low power consumption.

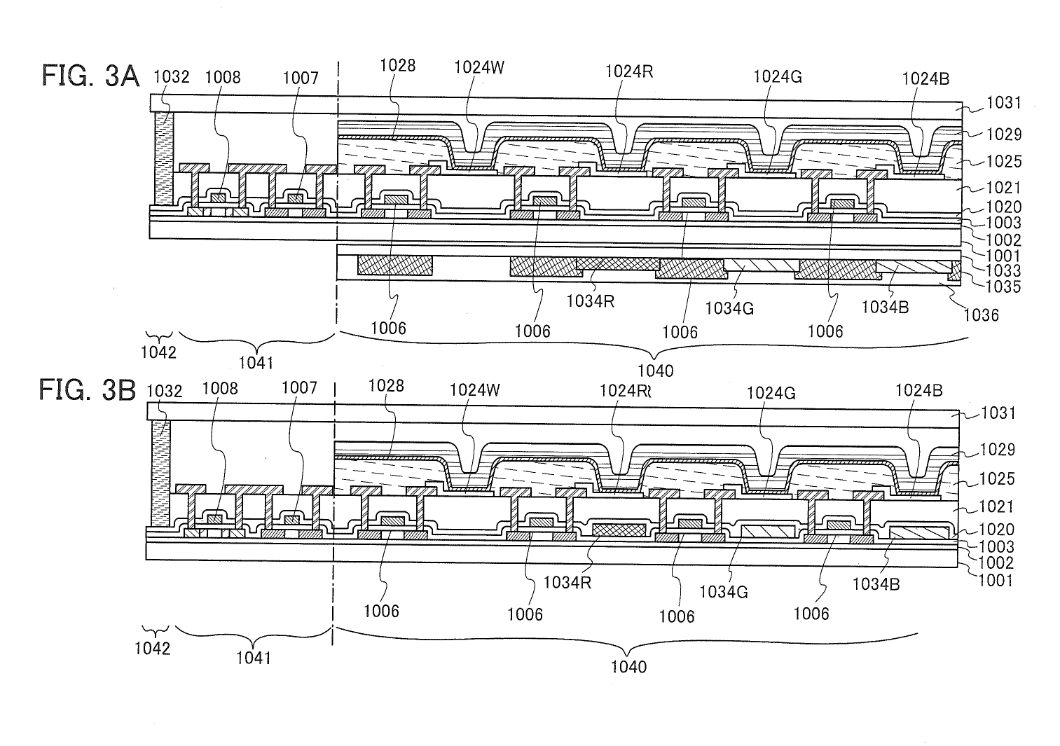

FIGS. 3A and 3B each illustrate an example of a light-emitting device in which full color display is achieved by formation of a light-emitting element exhibiting white light emission and with the use of coloring layers (color filters) and the like. In FIG. 3A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting elements, a partition 1025, an EL layer 1028, a second electrode 1029, a sealing substrate 1031, a sealing material 1032, and the like are illustrated.

In FIG. 3A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 3A, light emitted from part of the light-emitting layer does not pass through the coloring layers, while light emitted from the other part of the light-emitting layer passes through the coloring layers. Since light which does not pass through the coloring layers is white and light which passes through any one of the coloring layers is red, green, or blue, an image can be displayed using pixels of the four colors.

FIG. 3B illustrates an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

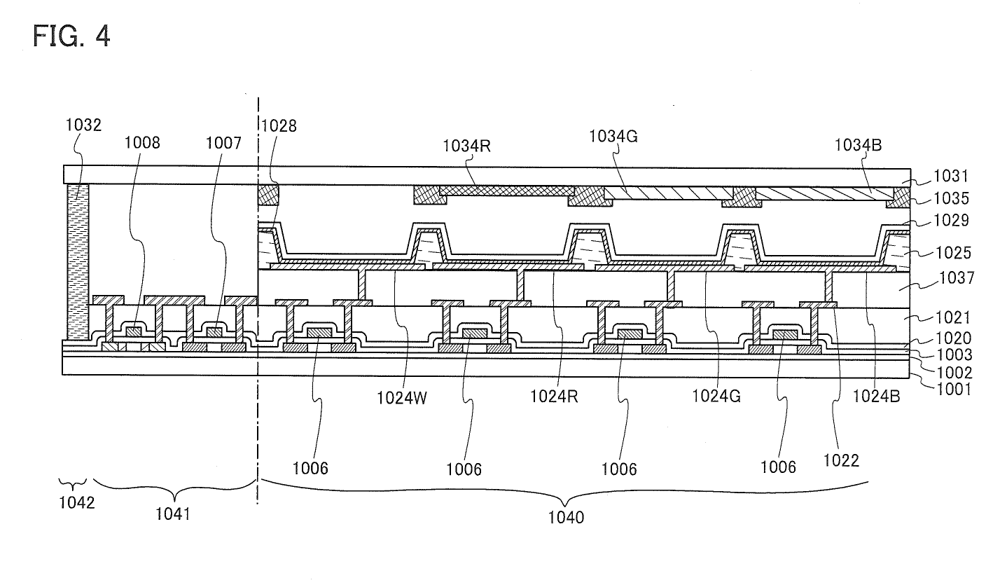

The above-described light-emitting device is a light-emitting device having a structure in which light is extracted from the substrate 1001 side where FETs are formed (a bottom emission structure), but may be a light-emitting device having a structure in which light is extracted from the sealing substrate 1031 side (a top emission structure). FIG. 4 is a cross-sectional view of a light-emitting device having a top emission structure. In this case, a substrate which does not transmit light can be used as the substrate 1001. The process up to the step of forming a connection electrode which connects the FET and the anode of the light-emitting element is performed in a manner similar to that of the light-emitting device having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The first electrodes 1024W, 1024R, 1024G, and 1024B of the light-emitting elements each serve as an anode here, but may serve as a cathode. Furthermore, in the case of a light-emitting device having a top emission structure as illustrated in FIG. 4, the first electrodes are preferably reflective electrodes. The EL layer 1028 is formed to have a structure similar to the structure of the EL layer 103, which is described in Embodiment 1, with which white light emission can be obtained.

In the case of a top emission structure as illustrated in FIG. 4, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) and the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the light-emitting device having a top emission structure, a microcavity structure can be favorably employed. A light-emitting element with a microcavity structure is formed with the use of a reflective electrode as the first electrode and a semi-transmissive and semi-reflective electrode as the second electrode. The light-emitting element with a microcavity structure includes at least an EL layer between the reflective electrode and the semi-transmissive and semi-reflective electrode, which includes at least a light-emitting layer serving as a light-emitting region.

Note that the reflective electrode has a visible light reflectivity of 40% to 100%, preferably 70% to 100%, and a resistivity of 1×10⁻² Ωcm or lower. In addition, the semi-transmissive and semi-reflective electrode has a visible light reflectivity of 20% to 80%, preferably 40% to 70%, and a resistivity of 1×10⁻² Ωcm or lower.

Light emitted from the light-emitting layer included in the EL layer is reflected and resonated by the reflective electrode and the semi-transmissive and semi-reflective electrode.

In the light-emitting element, by changing thicknesses of the transparent conductive film, the composite material, the carrier-transport material, and the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of color to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer. The tandem light-emitting element may be combined with a plurality of EL layers; for example, a light-emitting element may have a structure in which a plurality of EL layers are provided, a charge-generation layer is provided between the EL layers, and each EL layer includes a plurality of light-emitting layers or a single light-emitting layer.

With the microcavity structure, emission intensity with a specific wavelength in the front direction can be increased, whereby power consumption can be reduced. Note that in the case of a light-emitting device which displays images with subpixels of four colors, red, yellow, green, and blue, the light-emitting device can have favorable characteristics because the luminance can be increased owing to yellow light emission and each subpixel can employ a microcavity structure suitable for wavelengths of the corresponding color.

The light-emitting device in this embodiment is manufactured using the light-emitting element described in Embodiment 1 and thus can have favorable characteristics. Specifically, since the light-emitting element described in Embodiment 1 has a long lifetime, the light-emitting device can have high reliability. Since the light-emitting device using the light-emitting element described in Embodiment 1 has high luminous efficiency, the light-emitting device can achieve low power consumption.

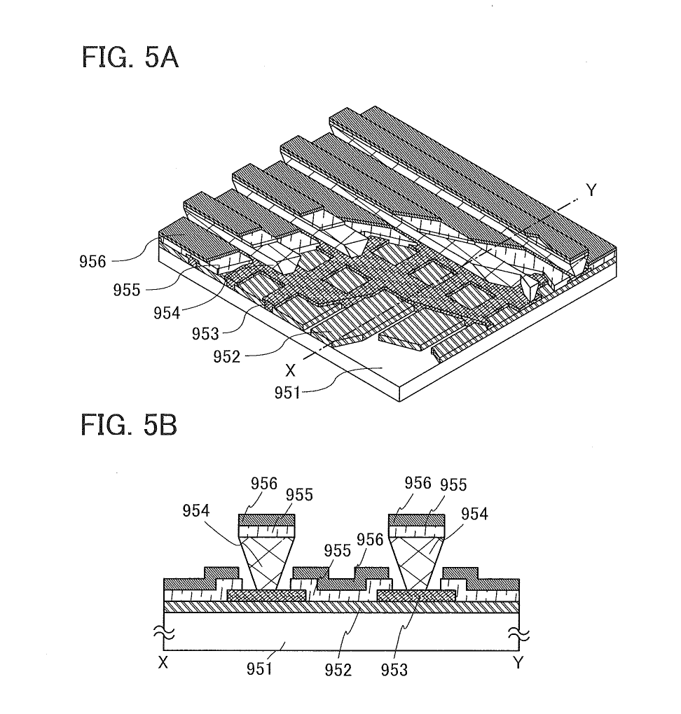

An active matrix light-emitting device is described above, whereas a passive matrix light-emitting device is described below. FIGS. 5A and 5B illustrate a passive matrix light-emitting device manufactured using the present invention. Note that FIG. 5A is a perspective view of the light-emitting device, and FIG. 5B is a cross-sectional view taken along line X-Y in FIG. 5A. In FIGS. 5A and 5B, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side of the trapezoid which is parallel to the surface of the insulating layer 953 and is in contact with the insulating layer 953) is shorter than the upper side (a side of the trapezoid which is parallel to the surface of the insulating layer 953 and is not in contact with the insulating layer 953). The partition layer 954 thus provided can prevent defects in the light-emitting element due to static electricity or others. The passive-matrix light-emitting device also includes the light-emitting element described in Embodiment 1; thus, the light-emitting device can have high reliability or low power consumption.

Since many minute light-emitting elements arranged in a matrix in the light-emitting device described above can each be controlled, the light-emitting device can be suitably used as a display device for displaying images.

This embodiment can be freely combined with any of the other embodiments.

### Embodiment 3

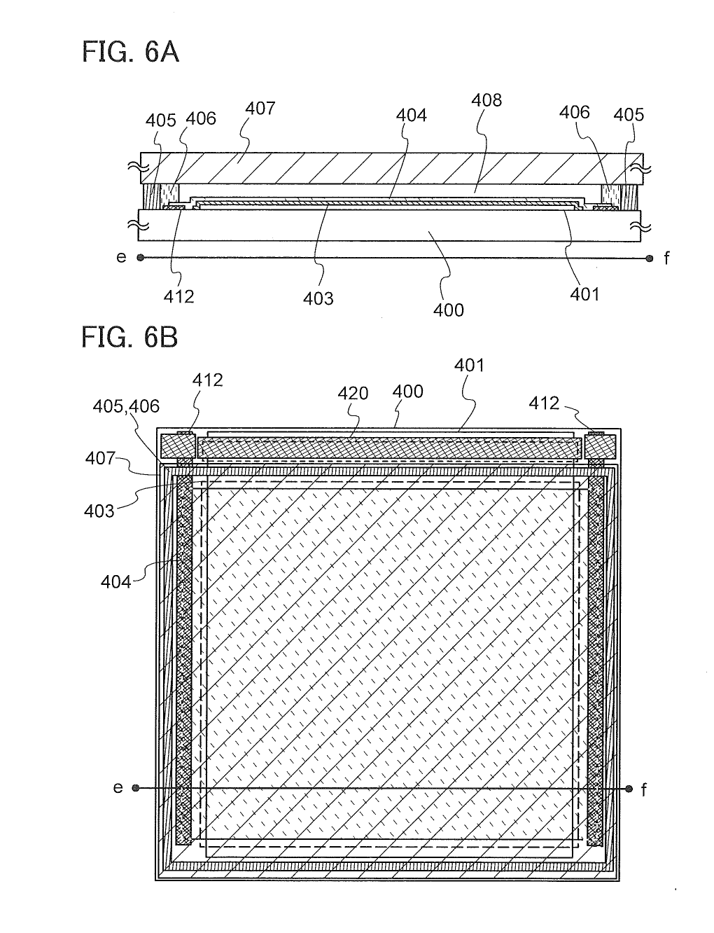

In this embodiment, an example in which the light-emitting element described in Embodiment 1 is used for a lighting device will be described with reference to FIGS. 6A and 6B. FIG. 6B is a top view of the lighting device, and FIG. 6A is a cross-sectional view taken along line e-f in FIG. 6B.

In the lighting device in this embodiment, a first electrode 401 is formed over a substrate 400 which is a support and has a light-transmitting property. The first electrode 401 corresponds to the anode 101 in Embodiment 1. When light is extracted through the first electrode 401 side, the first electrode 401 is formed using a material having a light-transmitting property.

A pad 412 for applying voltage to a second electrode 404 is provided over the substrate 400.

An EL layer 403 is formed over the first electrode 401. The structure of the EL layer 403 corresponds to, for example, the structure of the EL layer 103 in Embodiment 1. Refer to the descriptions for the structure.

The second electrode 404 is formed to cover the EL layer 403. The second electrode 404 corresponds to the cathode 102 in Embodiment 1. The second electrode 404 is formed using a material having high reflectance when light is extracted through the first electrode 401 side. The second electrode 404 is connected to the pad 412, whereby voltage is applied.

As described above, the lighting device described in this embodiment includes a light-emitting element including the first electrode 401, the EL layer 403, and the second electrode 404. Since the light-emitting element is a light-emitting element with high luminous efficiency, the lighting device in this embodiment can be a lighting device having low power consumption.

The substrate 400 provided with the light-emitting element having the above structure is fixed to a sealing substrate 407 with sealing materials 405 and 406 and sealing is performed, whereby the lighting device is completed. It is possible to use only either the sealing material 405 or the sealing material 406. The inner sealing material 406 (not illustrated in FIG. 6B) can be mixed with a desiccant which enables moisture to be adsorbed, increasing reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

The lighting device described in this embodiment includes as an EL element the light-emitting element described in Embodiment 1; thus, the light-emitting device can have high reliability. The light-emitting device can also have high heat resistance.

### Embodiment 4

In this embodiment, examples of electronic devices each including the light-emitting element described in Embodiment 1 are described. The light-emitting element described in Embodiment 1 has a long lifetime and high reliability. As a result, the electronic devices described in this embodiment can each include a light-emitting portion having high reliability.

Examples of the electronic devices to which the above light-emitting element is applied include television devices (also referred to as TV or television receivers), monitors for computers and the like, cameras such as digital cameras and digital video cameras, digital photo frames, mobile phones (also referred to as cell phones or mobile phone devices), portable game machines, portable information terminals, audio playback devices, large game machines such as pachinko machines, and the like. Specific examples of these electronic devices are given below.

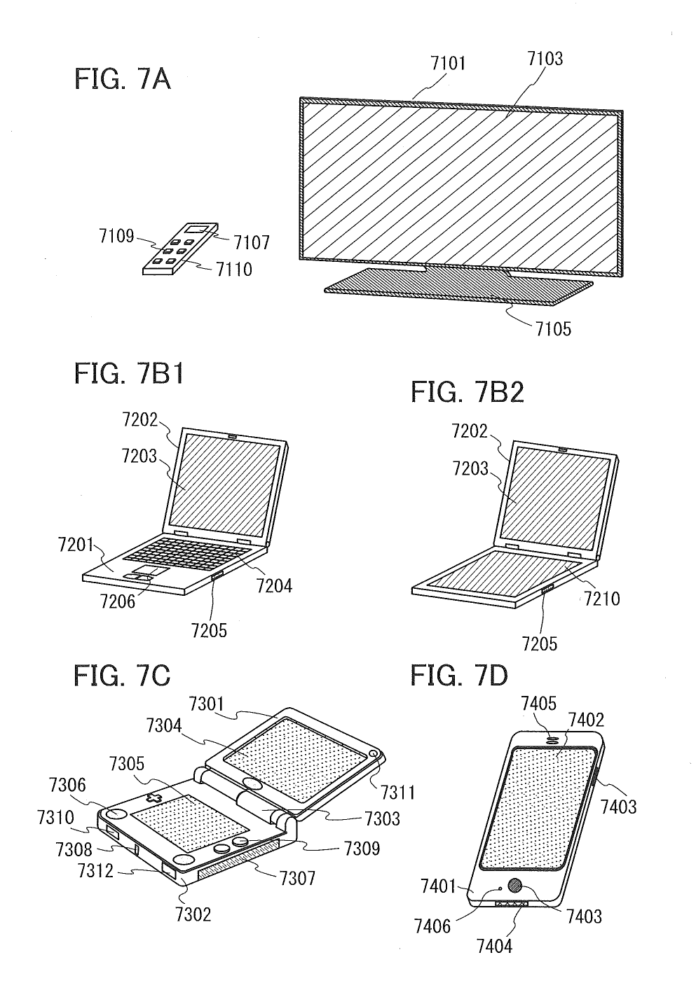

FIG. 7A illustrates an example of a television device. In the television device, a display portion 7103 is incorporated in a housing 7101. Here, the housing 7101 is supported by a stand 7105. Images can be displayed on the display portion 7103, and in the display portion 7103, the light-emitting elements each described in Embodiment 1 are arranged in a matrix.

Operation of the television device can be performed with an operation switch of the housing 7101 or a separate remote controller 7110. With operation keys 7109 of the remote controller 7110, channels and volume can be controlled and images displayed on the display portion 7103 can be controlled. The remote controller 7110 may be provided with a display portion 7107 for displaying data output from the remote controller 7110.

Note that the television device is provided with a receiver, a modem, and the like. With the use of the receiver, general television broadcasting can be received. Moreover, when the television device is connected to a communication network with or without wires via the modem, one-way (from a sender to a receiver) or two-way (between a sender and a receiver or between receivers) information communication can be performed.

FIG. 7B1 illustrates a computer, which includes a main body 7201, a housing 7202, a display portion 7203, a keyboard 7204, an external connection port 7205, a pointing device 7206, and the like. Note that this computer is manufactured by arranging light-emitting elements, each of which is similar to that described in Embodiment 1, in a matrix in the display portion 7203. The computer illustrated in FIG. 7B1 may have a structure illustrated in FIG. 7B2. The computer illustrated in FIG. 7B2 is provided with a second display portion 7210 instead of the keyboard 7204 and the pointing device 7206. The second display portion 7210 has a touch screen, and input can be performed by operation of images, which are displayed on the second display portion 7210, with a finger or a dedicated pen. The second display portion 7210 can also display images other than the display for input. The display portion 7203 may also have a touch screen. Connecting the two screens with a hinge can prevent troubles; for example, the screens can be prevented from being cracked or broken while the computer is being stored or carried.

FIG. 7C illustrates a portable game machine having two housings, a housing 7301 and a housing 7302, which are connected with a joint portion 7303 so that the portable game machine can be folded. The housing 7301 incorporates a display portion 7304 in which the light-emitting elements each described in Embodiment 1 are arranged in a matrix, and the housing 7302 incorporates a display portion 7305. In addition, the portable game machine illustrated in FIG. 7C includes a speaker portion 7306, a recording medium insertion portion 7307, an LED lamp 7308, input means (an operation key 7309, a connection terminal 7310, a sensor 7311 (a sensor having a function of measuring or sensing force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), and a microphone 7312), and the like. Needless to say, the structure of the portable game machine is not limited to the above as long as the display portion in which the light-emitting elements each described in Embodiment 1 are arranged in a matrix is used as either the display portion 7304 or the display portion 7305, or both, and the structure can include other accessories as appropriate. The portable game machine illustrated in FIG. 7C has a function of reading out a program or data stored in a recoding medium to display it on the display portion, and a function of sharing information with another portable game machine by wireless communication. Note that functions of the portable game machine illustrated in FIG. 7C are not limited to them, and the portable game machine can have various functions.

FIG. 7D illustrates an example of a portable terminal. The mobile phone is provided with a display portion 7402 incorporated in a housing 7401, operation buttons 7403, an external connection port 7404, a speaker 7405, a microphone 7406, and the like. Note that the mobile phone 7400 has the display portion 7402 in which the light-emitting elements each described in Embodiment 1 are arranged in a matrix.

When the display portion 7402 of the portable terminal illustrated in FIG. 7D is touched with a finger or the like, data can be input into the portable terminal. In this case, operations such as making a call and creating an e-mail can be performed by touching the display portion 7402 with a finger or the like.

There are mainly three screen modes of the display portion 7402. The first mode is a display mode mainly for displaying an image. The second mode is an input mode mainly for inputting information such as characters. The third mode is a display-and-input mode in which two modes of the display mode and the input mode are combined.

For example, in the case of making a call or creating an e-mail, a character input mode is selected for the display portion 7402 so that characters displayed on a screen can be input. In this case, it is preferable to display a keyboard or number buttons on almost the entire screen of the display portion 7402.

When a sensing device including a sensor such as a gyroscope or an acceleration sensor for detecting inclination is provided inside the portable terminal, display on the screen of the display portion 7402 can be automatically changed in direction by determining the orientation of the portable terminal (whether the portable terminal is placed horizontally or vertically).

The screen modes are switched by touch on the display portion 7402 or operation with the operation buttons 7403 of the housing 7401. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, if a signal detected by an optical sensor in the display portion 7402 is detected and the input by touch on the display portion 7402 is not performed for a certain period, the screen mode may be controlled so as to be changed from the input mode to the display mode.

The display portion 7402 may function as an image sensor. For example, an image of a palm print, a fingerprint, or the like is taken by the display portion 7402 while in touch with the palm or the finger, whereby personal authentication can be performed. Furthermore, by providing a backlight or a sensing light source which emits near-infrared light in the display portion, an image of a finger vein, or a palm vein can be taken.

Note that the structure described in this embodiment can be combined with any of the structures described in Embodiments 1 to 4 as appropriate.

As described above, the application range of the light-emitting device including the light-emitting element described in Embodiment 1 is wide so that this light-emitting device can be applied to electronic devices in a variety of fields. With the use of the light-emitting element described in Embodiment 1, a highly reliable electronic device can be obtained.

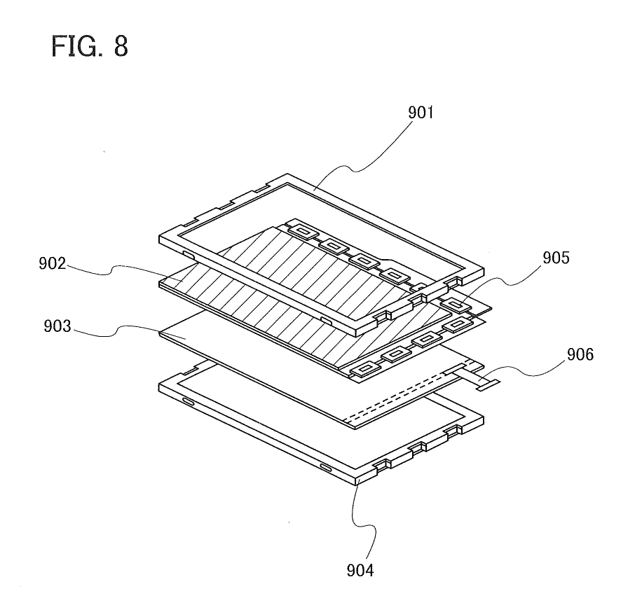

FIG. 8 illustrates an example of a liquid crystal display device using the light-emitting element described in Embodiment 1 for a backlight. The liquid crystal display device illustrated in FIG. 8 includes a housing 901, a liquid crystal layer 902, a backlight unit 903, and a housing 904. The liquid crystal layer 902 is connected to a driver IC 905. The light-emitting element described in Embodiment 1 is used for the backlight unit 903, to which current is supplied through a terminal 906.

The light-emitting element described in Embodiment 1 is used for the backlight of the liquid crystal display device; thus, the backlight can have reduced power consumption. In addition, the use of the light-emitting element described in Embodiment 1 enables manufacture of a planar-emission lighting device and further a larger-area planar-emission lighting device; therefore, the backlight can be a larger-area backlight, and the liquid crystal display device can also be a larger-area device. Furthermore, the light-emitting device including the light-emitting element described in Embodiment 1 can be thinner than a conventional one; accordingly, the display device can also be thinner.

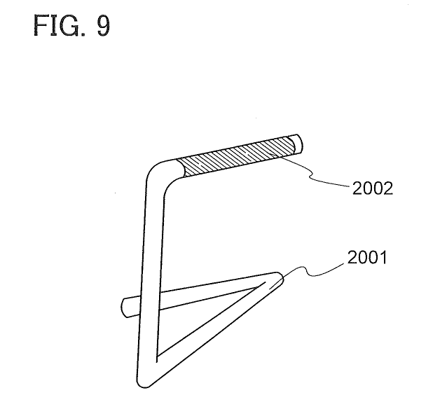

FIG. 9 illustrates an example in which the light-emitting element described in Embodiment 1 is used for a table lamp which is a lighting device. The table lamp illustrated in FIG. 9 includes a housing 2001 and a light source 2002, and the lighting device described in Embodiment 3 may be used for the light source 2002.

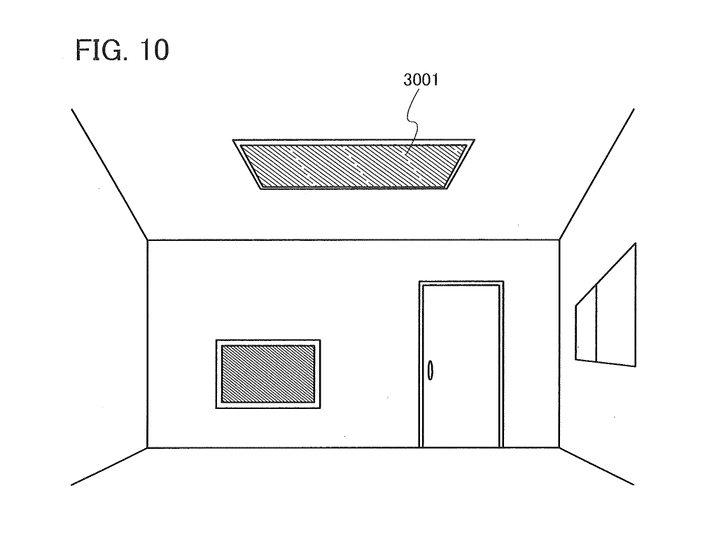

FIG. 10 illustrates an example in which the light-emitting element described in Embodiment 1 is used for an indoor lighting device 3001. Since the light-emitting element described in Embodiment 1 is highly reliable, the lighting device can be highly reliable. Furthermore, since the light-emitting element described in Embodiment 1 can have a large area, the light-emitting element can be used for a large-area lighting device. Furthermore, since the light-emitting element described in Embodiment 1 is thin, the light-emitting element can be used for a lighting device having a reduced thickness.

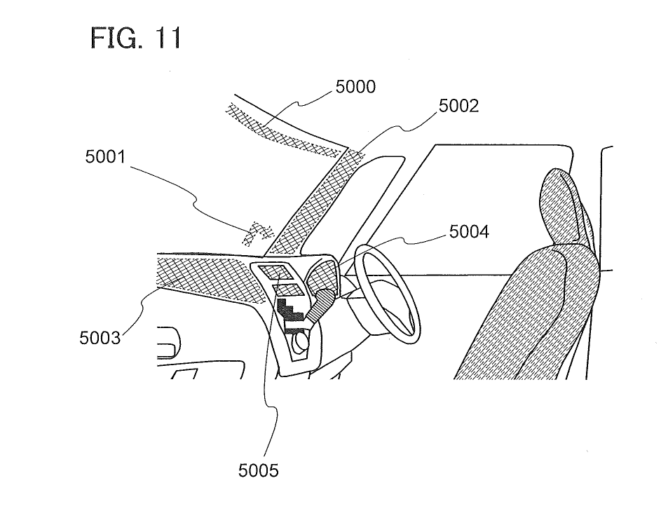

The light-emitting element described in Embodiment 1 can also be used for an automobile windshield or an automobile dashboard. FIG. 11 illustrates one mode in which the light-emitting element described in Embodiment 1 is used for an automobile windshield and an automobile dashboard. Display regions 5000 to 5005 each include the light-emitting element described in Embodiment 1.

The display region 5000 and the display region 5001 are display devices provided in the automobile windshield in which the light-emitting elements each described in Embodiment 1 are incorporated. The light-emitting elements each described in Embodiment 1 can be formed into what is called a see-through display device, through which the opposite side can be seen, by including a first electrode and a second electrode formed of electrodes having a light-transmitting property. Such see-through display devices can be provided even in the automobile windshield, without hindering the vision. Note that in the case where a driving transistor or the like is provided, a transistor having a light-transmitting property, such as an organic transistor using an organic semiconductor material or a transistor using an oxide semiconductor, is preferably used.

The display region 5002 is a display device provided in a pillar portion in which the light-emitting elements each described in Embodiment 1 are incorporated. The display region 5002 can compensate for the view hindered by the pillar portion by showing an image taken by an imaging unit provided in the car body. Similarly, the display region 5003 provided in the dashboard can compensate for the view hindered by the car body by showing an image taken by an imaging unit provided in the outside of the car body, which leads to elimination of blind areas and enhancement of safety. Showing an image so as to compensate for the area which a driver cannot see makes it possible for the driver to confirm safety easily and comfortably.

The display region 5004 and the display region 5005 can provide a variety of kinds of information such as navigation data, a speed meter, a tachometer, a mileage, a fuel level, a gearshift state, and air-condition setting. The content or layout of the display can be freely changed by a user as appropriate. Note that such information can also be shown by the display regions 5000 to 5003. The display regions 5000 to 5005 can also be used as lighting devices.

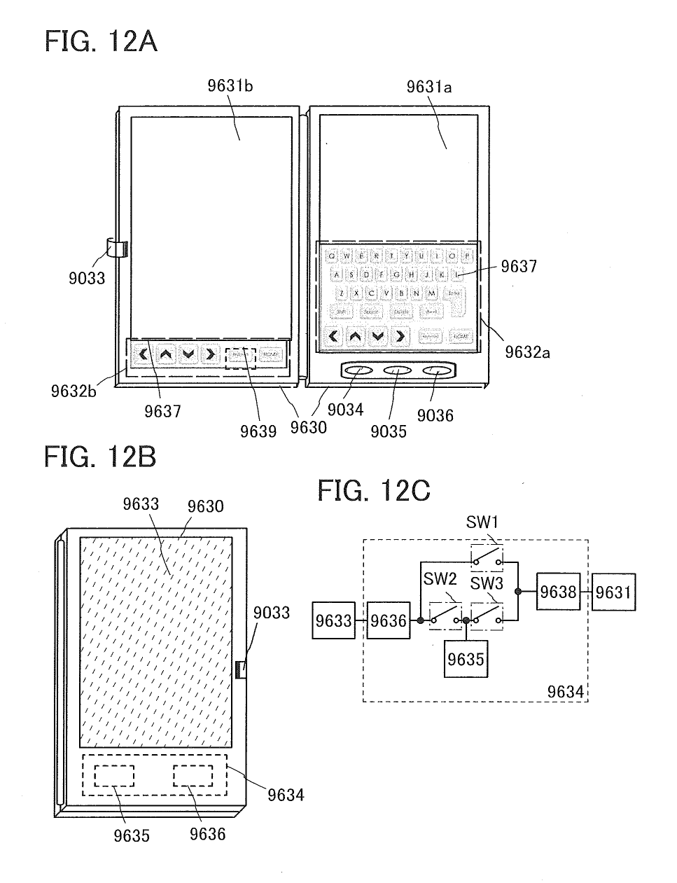

FIGS. 12A and 12B illustrate an example of a foldable tablet terminal. FIG. 12A illustrates the tablet terminal which is unfolded. The tablet terminal includes a housing 9630, a display portion 9631a, a display portion 9631b, a display mode switch 9034, a power switch 9035, a power-saving mode switch 9036, a clasp 9033, and an operation switch 9038. Note that in the tablet terminal, one or both of the display portion 9631a and the display portion 9631b is/are formed using a light-emitting device which includes the light-emitting element described in Embodiment 1.

Part of the display portion 9631a can be a touchscreen region 9632a and data can be input when a displayed operation key 9637 is touched. Although half of the display portion 9631a has only a display function and the other half has a touchscreen function, one embodiment of the present invention is not limited to the structure. The whole display portion 9631a may have a touchscreen function. For example, a keyboard can be displayed on the entire region of the display portion 9631a so that the display portion 9631a is used as a touchscreen, and the display portion 9631b can be used as a display screen.

Like the display portion 9631a, part of the display portion 9631b can be a touchscreen region 9632b. When a switching button 9639 for showing/hiding a keyboard on the touchscreen is touched with a finger, a stylus, or the like, the keyboard can be displayed on the display portion 9631b.

Touch input can be performed in the touchscreen region 9632a and the touchscreen region 9632b at the same time.

The display mode switch 9034 can switch the display between portrait mode, landscape mode, and the like, and between monochrome display and color display, for example. The power-saving mode switch 9036 can control display luminance in accordance with the amount of external light in use of the tablet terminal sensed by an optical sensor incorporated in the tablet terminal. Another sensing device including a sensor such as a gyroscope or an acceleration sensor for sensing inclination may be incorporated in the tablet terminal, in addition to the optical sensor.

Although FIG. 12A illustrates an example in which the display portion 9631a and the display portion 9631b have the same display area, one embodiment of the present invention is not limited to the example. The display portion 9631a and the display portion 9631b may have different display areas and different display quality. For example, higher definition images may be displayed on one of the display portions 9631a and 9631b.

FIG. 12B illustrates the tablet terminal which is folded. The tablet terminal in this embodiment includes the housing 9630, a solar cell 9633, a charge and discharge control circuit 9634, a battery 9635, and a DCDC converter 9636. In FIG. 12B, a structure including the battery 9635 and the DCDC converter 9636 is illustrated as an example of the charge and discharge control circuit 9634.

Since the tablet terminal is foldable, the housing 9630 can be closed when the tablet terminal is not in use. As a result, the display portion 9631a and the display portion 9631b can be protected, thereby providing a tablet terminal with high endurance and high reliability for long-term use.

The tablet terminal illustrated in FIGS. 12A and 12B can have other functions such as a function of displaying various kinds of data (e.g., a still image, a moving image, and a text image), a function of displaying a calendar, a date, the time, or the like on the display portion, a touch-input function of operating or editing the data displayed on the display portion by touch input, and a function of controlling processing by various kinds of software (programs).

The solar cell 9633 provided on a surface of the tablet terminal can supply power to the touchscreen, the display portion, a video signal processing portion, or the like. Note that a structure in which the solar cell 9633 is provided on one or both surfaces of the housing 9630 is preferable because the battery 9635 can be charged efficiently.

The structure and operation of the charge and discharge control circuit 9634 illustrated in FIG. 12B will be described with reference to a block diagram of FIG. 12C. FIG. 12C illustrates the solar cell 9633, the battery 9635, the DCDC converter 9636, a converter 9638, switches SW1 to SW3, and a display portion 9631. The battery 9635, the DCDC converter 9636, the converter 9638, and the switches SW1 to SW3 correspond to the charge and discharge control circuit 9634 illustrated in FIG. 12B.

First, description is made on an example of the operation in the case where power is generated by the solar cell 9633 with the use of external light. The voltage of the power generated by the solar cell is raised or lowered by the DCDC converter 9636 so as to be voltage for charging the battery 9635. Then, when power from the solar cell 9633 is used for the operation of the display portion 9631, the switch SW1 is turned on and the voltage of the power is raised or lowered by the converter 9638 so as to be voltage needed for the display portion 9631. When images are not displayed on the display portion 9631, the switch SW1 is turned off and the switch SW2 is turned on so that the battery 9635 is charged.

Although the solar cell 9633 is described as an example of a power generation means, there is no particular limitation on the power generation means, and the battery 9635 may be charged by another power generation means such as a piezoelectric element or a thermoelectric conversion element (Peltier element). The battery 9635 may be charged by a non-contact power transmission module capable of performing charging by transmitting and receiving power wirelessly (without contact), or any of the other charge means used in combination, and the power generation means is not necessarily provided.

One embodiment of the present invention is not limited to the tablet terminal having the shape illustrated in FIGS. 12A to 12C as long as the display portion 9631 is included.

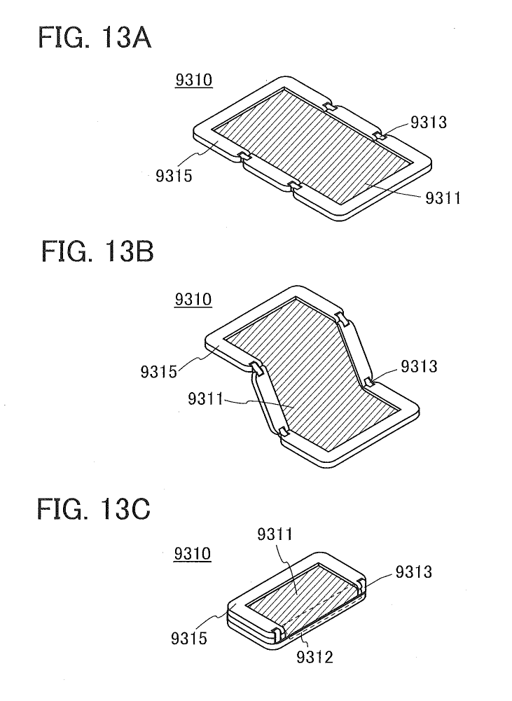

FIGS. 13A to 13C illustrate a foldable portable information terminal 9310. FIG. 13A illustrates the portable information terminal 9310 that is opened. FIG. 13B illustrates the portable information terminal 9310 that is being opened or being folded. FIG. 13C illustrates the portable information terminal 9310 that is folded. The portable information terminal 9310 is highly portable when folded. When the portable information terminal 9310 is opened, a seamless large display region is highly browsable.

A display panel 9311 is supported by three housings 9315 joined together by hinges 9313. The display panel 9311 may be a touch panel (an input/output device) including a touch sensor (an input device). By bending the display panel 9311 at a connection portion between two housings 9315 with the use of the hinges 9313, the portable information terminal 9310 can be reversibly changed in shape from an opened state to a folded state. The light-emitting device of one embodiment of the present invention can be used for the display panel 9311. A display region 9312 in the display panel 9311 includes a display region that is positioned at a side surface of the portable information terminal 9310 that is folded. On the display region 9312, information icons, frequently-used applications, file shortcuts to programs, and the like can be displayed, and confirmation of information and start of application can be smoothly performed.

### Example 1

In this example, methods for fabricating light-emitting elements 1 to 5 each of which is a light-emitting element of the present invention and comparative light-emitting elements 1 to 4 and characteristics of the light-emitting elements will be described in detail. Structural formulae of organic compounds used in this example are shown below.

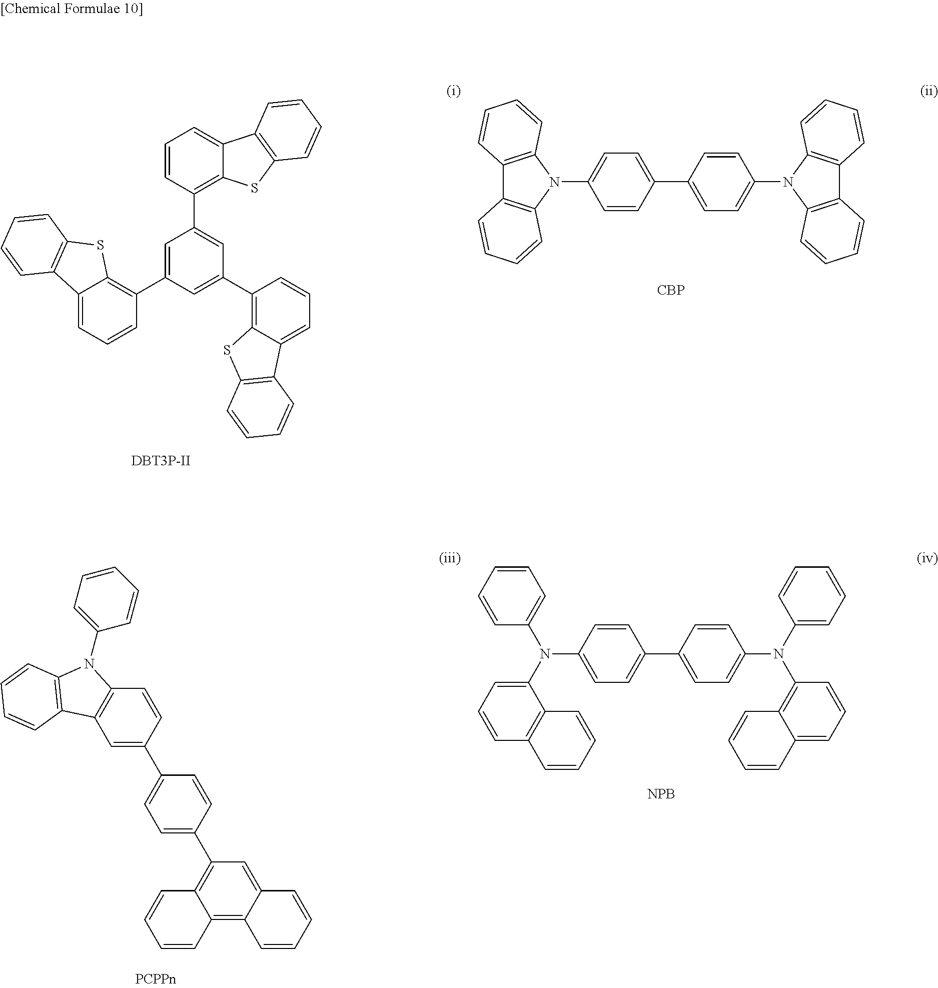

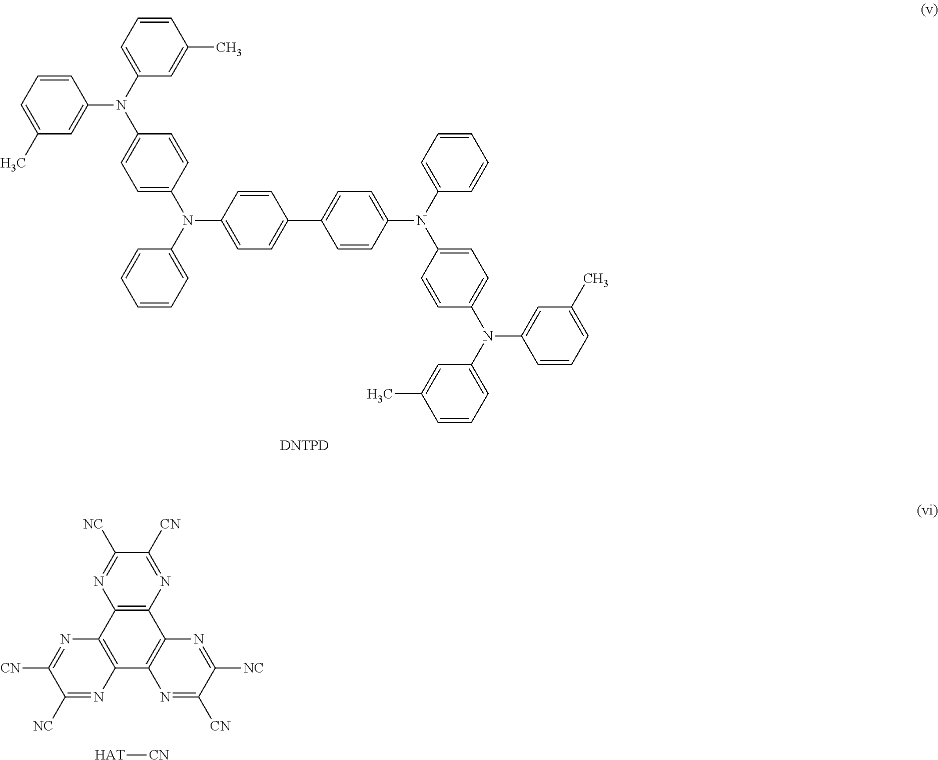

### (Method for Fabricating Light-Emitting Element 1)

First, indium tin oxide containing silicon oxide (ITSO) was formed over a glass substrate by a sputtering method to form the cathode 102. The thickness of the cathode 102 was set to 70 nm and the area of the electrode was set to 2 mm×2 mm.

Next, in pretreatment for forming the light-emitting element over the substrate, a surface of the substrate was washed with water and baked at 200° C. for one hour, and then UV ozone treatment was performed for 370 seconds.

After that, the substrate over which the cathode 102 was formed was fixed to a substrate holder of a spin coater such that a surface over which the cathode 102 was formed faced upward. Then, a dispersion containing zinc oxide in 2-propanol at a weight ratio of 0.6% obtained by diluting a 2-propanol dispersion containing nanoparticles of zinc oxide at a weight ratio of 2.5% (product No. 793361, purchased from Sigma-Aldrich Co.) was applied to the cathode 102 and the substrate spun at 500 rpm for 60 seconds. This substrate was vacuum baked in a chamber at a pressure of 1 Pa to 10 Pa at 100° C. for 60 minutes and then cooled down for approximately 30 minutes, whereby the electron injection/transport layer 112 was formed. The electron injection/transport layer 112 was formed to have a thickness of 30 nm.

Next, the substrate over which the electron injection/transport layer 112 was formed was transferred to a glove box filled with a nitrogen atmosphere, a 5-mg/mL indium phosphide/zinc sulfide (ligand: oleylamine) toluene solution at an emission wavelength of 530 nm (product No. 776750, purchased from Sigma-Aldrich Co.) was applied to the electron injection/transport layer 112, and the substrate spun at 500 rpm for 60 seconds. This substrate was vacuum baked in a chamber at a pressure of 1 Pa to 10 Pa at 130° C. for 30 minutes and then cooled down for approximately 30 minutes, whereby the light-emitting layer 113 was formed. The light-emitting layer 113 was formed to have a thickness of 10 nm.

Subsequently, the hole-transport layer 111-2 was formed in the following manner: the substrate was transferred to a vacuum evaporation apparatus where the pressure was reduced to approximately 10⁻⁴ Pa, the substrate over which the light-emitting layer 113 was formed was fixed to a substrate holder provided in the vacuum evaporation apparatus such that a surface over which the light-emitting layer 113 was formed faced downward, and 1,3,5-tri-(4-dibenzothiophenyl)-benzene (abbreviation: DBT3P-II) represented by Structural Formula (i) was deposited to a thickness of 20 nm over the light-emitting layer 113 by an evaporation method using resistance heating.

Then, DBT3P-II represented by the structural formula and a molybdenum(VI) oxide were deposited by co-evaporation over the hole-transport layer 111-2 to form the hole-injection layer 111-1. The hole-injection layer 111-1 was formed to have a thickness of 30 nm such that the weight ratio of DBT3P-II to the molybdenum oxide was 4:2.

After the hole-injection layer 111-1 was formed, as the anode 101, aluminum was deposited by evaporation to a thickness of 200 nm. In this manner, the light-emitting element 1 of this example was fabricated.

### (Method for Fabricating Light-Emitting Element 2)

The light-emitting element 2 was fabricated in the same manner as the light-emitting element 1 except that 4,4′-di(N-carbazolyl)biphenyl (abbreviation: CBP) represented by the structural formula (ii) was used in the hole-injection layer 111-1 and the hole-transport layer 111-2 instead of DBT3P-II.

### (Method for Fabricating Light-Emitting Element 3)

The light-emitting element 3 was fabricated in the same manner as the light-emitting element 1 except that 3-[4-(9-phenanthryl)-phenyl]-9-phenyl-9H-carbazole (abbreviation: PCPPn) represented by the structural formula (iii) was used in the hole-injection layer 111-1 and the hole-transport layer 111-2 instead of DBT3P-II.

### (Method for Fabricating Light-Emitting Element 4)

The light-emitting element 4 was fabricated in the same manner as the light-emitting element 1 except that 4,4′-bis[N-(1-naphthyl)-N-phenylamino]biphenyl (abbreviation: NPB) represented by the structural formula (iv) was used in the hole-injection layer 111-1 and the hole-transport layer 111-2 instead of DBT3P-II.

### (Method for Fabricating Light-Emitting Element 5)

The light-emitting element 5 was fabricated in the same manner as the light-emitting element 1 except that N,N′-bis{4-[bis(3-methylphenyl)amino]phenyl}-N,N′-diphenyl-(1,1′-biphenyl)-4,4′-diamine (abbreviation: DNTPD) represented by the structural formula (v) was used in the hole-injection layer 111-1 and the hole-transport layer 111-2 instead of DBT3P-II.

### (Method for Fabricating Comparative Light-Emitting Element 1)

The comparative light-emitting element 1 was fabricated in the same manner as the light-emitting element 1 except for the following steps of forming the electron injection/transport layer 112 and the hole-injection layer 111-1. A dispersion containing zinc oxide in 2-propanol at a weight ratio of 2.0% obtained by diluting a 2-propanol dispersion containing nanoparticles of zinc oxide at a weight ratio of 2.5% (product No. 793361, purchased from Sigma-Aldrich Co.) was applied, the substrate spun at 3000 rpm for 30 seconds, and this substrate was vacuum baked in a chamber at a pressure of 1 Pa to 10 Pa at 120° C. for 10 minutes and then cooled down for approximately 30 minutes to form the electron injection/transport layer 112. The hole-injection layer 111-1 was formed using 2,3,6,7,10,11-hexacyano-1,4,5,8,9,12-hexaazatriphenylene (abbreviation: HAT-CN) represented by the structural formula (vi).

### (Method for Fabricating Comparative Light-Emitting Element 2)

The comparative light-emitting element 2 was fabricated in the same manner as the light-emitting element 2 except for the following steps of forming the electron injection/transport layer 112 and the hole-injection layer 111-1. A dispersion containing zinc oxide in 2-propanol at a weight ratio of 2.0% obtained by diluting a 2-propanol dispersion containing nanoparticles of zinc oxide at a weight ratio of 2.5% (product No. 793361, purchased from Sigma-Aldrich Co.) was applied, the substrate spun at 3000 rpm for 30 seconds, and this substrate was vacuum baked in a chamber at a pressure of 1 Pa to 10 Pa at 120° C. for 10 minutes and then cooled down for approximately 30 minutes to form the electron injection/transport layer 112. The hole-injection layer 111-1 was formed using HAT-CN represented by the structural formula (vi).

### (Method for Fabricating Comparative Light-Emitting Element 3)

The comparative light-emitting element 3 was fabricated in the same manner as the light-emitting element 3 except for the following steps of forming the electron injection/transport layer 112 and the hole-injection layer 111-1. A dispersion containing zinc oxide in 2-propanol at a weight ratio of 2.0% obtained by diluting a 2-propanol dispersion containing nanoparticles of zinc oxide at a weight ratio of 2.5% (product No. 793361, purchased from Sigma-Aldrich Co.) was applied, the substrate spun at 3000 rpm for 30 seconds, and this substrate was vacuum baked in a chamber at a pressure of 1 Pa to 10 Pa at 120° C. for 10 minutes and then cooled down for approximately 30 minutes to form the electron injection/transport layer 112. The hole-injection layer 111-1 was formed using HAT-CN represented by the structural formula (vi).

### (Method for Fabricating Comparative Light-Emitting Element 4)

The comparative light-emitting element 4 was fabricated in the same manner as the light-emitting element 4 except for the following steps of forming the electron injection/transport layer 112 and the hole-injection layer 111-1. A dispersion containing zinc oxide in 2-propanol at a weight ratio of 2.0% obtained by diluting a 2-propanol dispersion containing nanoparticles of zinc oxide at a weight ratio of 2.5% (product No. 793361, purchased from Sigma-Aldrich Co.) was applied, the substrate spun at 3000 rpm for 30 seconds, and this substrate was vacuum baked in a chamber at a pressure of 1 Pa to 10 Pa at 120° C. for 10 minutes and then cooled down for approximately 30 minutes to form the electron injection/transport layer 112. The hole-injection layer 111-1 was formed using HAT-CN represented by the structural formula (vi).

Table 1 lists the element structures of the light-emitting elements 1 to 5 and the comparative light-emitting elements 1 to 4.

TABLE 1

| | Electron | | | |
|---|---|---|---|---|
| | injection/ | Light- | Hole- | Hole- |
| | transport | emitting | transport | injection |
| | layer | layer | layer | layer |
| Thickness | 30 nm | 10 nm | 20 nm | 30 nm |
| Light-emitting | ZnO | InP/ZnS | DBT3P-II | DBT3P-II:MoOx |
| element 1 | | | | (4:2) |
| Light-emitting | | | CBP | CBP:MoOx |
| element 2 | | | | (4:2) |
| Light-emitting | | | PCPPn | PCPPn:MoOx |
| element 3 | | | | (42) |
| Light-emitting | | | NPB | NPB:MoOx |
| element 4 | | | | (4:2) |
| Light-emitting | | | DNTPD | DNTPD:MoOx |
| element 5 | | | | (4:2) |
| Comparative | | | DBT3P-II | HAT-CN |
| light-emitting | | | | |
| element 1 | | | | |
| Comparative | | | CBP | |
| light-emitting | | | | |
| element 2 | | | | |
| Comparative | | | PCPPn | |
| light-emitting | | | | |
| element 3 | | | | |
| Comparative | | | NPB | |
| light-emitting | | | | |
| element 4 | | | | |

As described above, the hole-injection layer of each of the light-emitting elements 1 to 5 contained the first substance which was an organic compound having a hole-transport property and the second substance having an electron acceptor property with respect to the first substance.

For each of the light-emitting elements 1 to 5 and the comparative light-emitting elements 1 to 4, the HOMO level and the LUMO level of the organic compound used for the hole-injection layer 111-1 and the valence band maximum (VB) and the conduction band minimum (CB) of the quantum dot used for the light-emitting layer were estimated by cyclic voltammetry (CV) and calculated from an optical band gap by photoelectron spectroscopy in air (PESA). The results are shown in the table below.

Note that CV measurement was performed with an electrochemical analyzer (ALS model 600A or 600C manufactured by BAS Inc.) as a measurement apparatus. Note that dehydrated dimethylformamide (DMF produced by Sigma-Aldrich Co., 99.8%, catalog No. 22705-6) was used as a solvent, and tetra-n-butylammonium perchlorate (n-Bu₄NClO₄ produced by Tokyo Chemical Industry Co., Ltd., catalog No. T0836), which was a supporting electrolyte, was dissolved in the solvent to obtain a concentration of 100 mmol/L. Furthermore, the object to be measured was also dissolved in the solvent to obtain a concentration of 2 mmol/L. A platinum electrode (PTE platinum electrode manufactured by BAS Inc.) was used as a working electrode, another platinum electrode (Pt counter electrode for VC-3 (5 cm) manufactured by BAS Inc.) was used as an auxiliary electrode, and an Ag/Ag⁺ electrode (RE7 reference electrode for nonaqueous solvent manufactured by BAS Inc.) was used as a reference electrode. Note that the CV measurement was performed at room temperature (20° C. to 25° C.). In addition, the scan speed for CV measurement was set to 0.1 V/sec, and an oxidation potential Ea [V] and a reduction potential Ec [V] with respect to the reference electrode were measured. Note that Ea represents an intermediate potential of an oxidation-reduction wave, and Ec represents an intermediate potential of a reduction-oxidation wave. Here, the potential energy of the reference electrode used in this example with respect to the vacuum level is found to be −4.94 [eV]; thus, the HOMO level and the LUMO level can be calculated by the following formulae: HOMO level [eV]=−4.94−Ea, and LUMO level [eV]=−4.94−Ec.

The measurement by photoelectron spectroscopy in air (PESA) was performed with a photoelectron spectrometer (AC-3 produced by Riken Keiki, Co., Ltd.).

TABLE 2

| | CV | | PESA | |
|---|---|---|---|---|
| | HOMO, | LUMO, | HOMO, | LUMO, |
| | VB (eV) | CB (eV) | VB (eV) | CB (eV) |
| Quantum dot | −5.79 | −3.51 | −5.83 | −3.51 |
| DBT3P-II | −6.22 | −2.35 | −6.20 | −2.70 |
| CBP | −5.87 | −2.19 | −6.15 | −2.68 |
| PCPPn | −5.80 | −2.24 | −5.91 | −2.38 |
| NPB | −5.38 | −2.18 | −5.54 | −2.48 |
| DNTPD | −5.16 | — | −5.36 | −2.24 |
| HAT-CN | (−7.77)*¹ | −4.41 | — | — |

*¹calculated from LUMO level and band gap

The light-emitting elements 1 to 5 and the comparative light-emitting elements 1 to 4 were each sealed using a glass substrate in a glove box containing a nitrogen atmosphere so as not to be exposed to the air (specifically, a sealing material was applied to surround the elements and UV treatment and heat treatment at 80° C. for 1 hour were performed at the time of sealing). Then, initial characteristics of these light-emitting elements were measured. Note that the measurements were performed at room temperature (in an atmosphere kept at 25° C.).

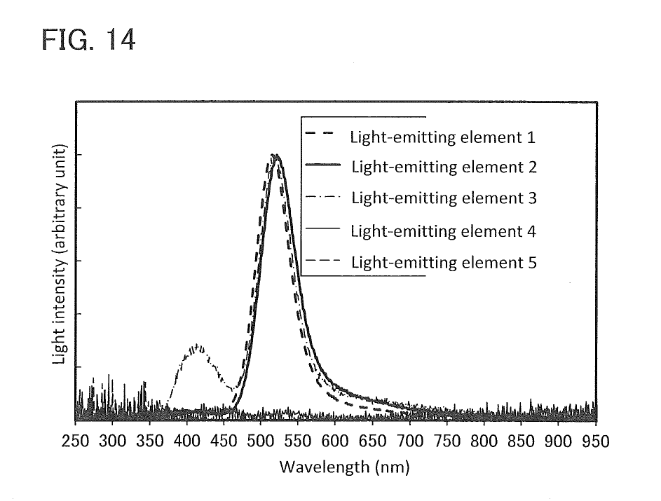

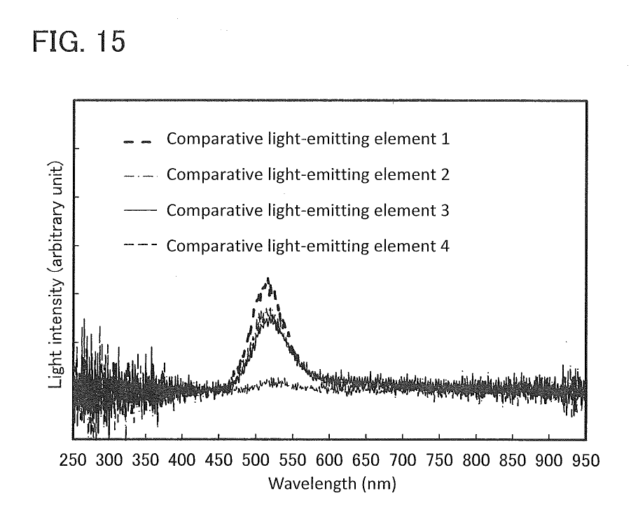

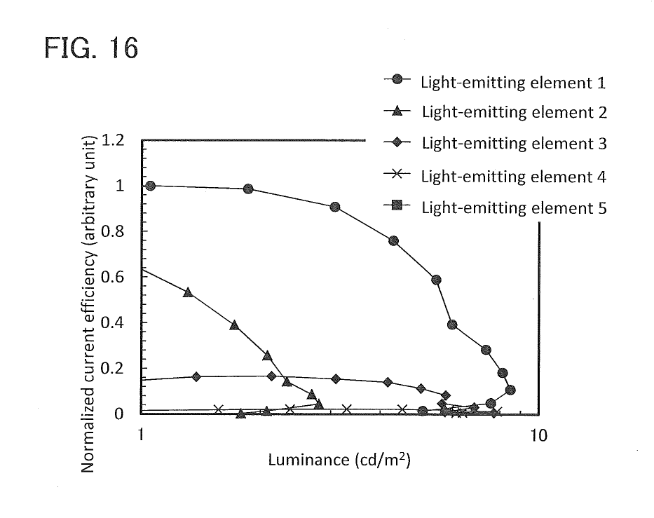

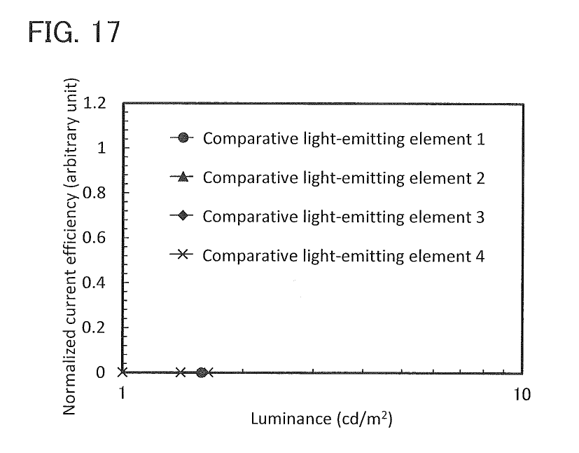

FIG. 14 and FIG. 15 show emission spectra of the light-emitting elements 1 to 5 and the comparative light-emitting elements 1 to 4, respectively, at a current density of 25 mA/cm². FIG. 16 and FIG. 17 show the current efficiency with respect to luminance, of the light-emitting elements 1 to 5 and the comparative light-emitting elements 1 to 4, respectively, which is normalized by the maximum current efficiency of the light-emitting element 1.

The results in FIG. 14 to FIG. 17 indicate that the light-emitting elements 1 to 4 and the comparative light-emitting elements 1 to 4 emitted light from the quantum dots used in this example. Note that in the light-emitting element 3, blue light emission attributed to the material of the hole-transport layer was mixed.

As apparent from the graphs, efficient light emission from the quantum dots was not able to be obtained in the comparative light-emitting elements 1 to 4 in each of which the HAT-CN was used for the hole-injection layer. This result indicates that a hole cannot be efficiently injected into the light-emitting layer even when a hole-transport material having a deep HOMO level is used for the hole-transport layer as long as HAT-CN is used for the hole-transport layer. The reason why efficient hole injection into the light-emitting layer was not able to be obtained even in the case of the comparative light-emitting elements 1 to 3 in which DBT3P-II, CBP, and PCPPn that had HOMO levels suitable for hole injection with respect to VB of the quantum dots were used is that HAT-CN was not able to extract an electron and thus a charge was not efficiently generated since the HOMO levels of their hole-transport materials were deep (specifically, −5.4 eV or lower).

Meanwhile, the results of the light-emitting element 1 to 5 shown in FIG. 14 and FIG. 16 probably have correlation to the HOMO levels of the hole-transport materials. As for the case of using the quantum dots used in this example, a hole was able to be injected into the light-emitting layer very suitably when a material having a HOMO level deeper than that of PCPPn was used. This means that it is preferable to use a material having a HOMO level comparable to or deeper than VB of the quantum dot as a hole-transport material.

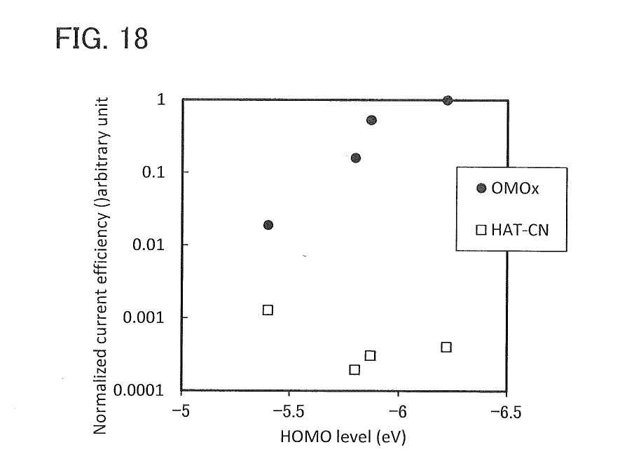

Next, for the examination of the correlation between the current efficiency and the HOMO level, Table 3 lists the HOMO levels of the hole-transport materials and the maximum current efficiency of the elements in the case of using HAT-CN or a structure (hereinafter, referred to as OMOx in some cases) including the first substance which is an organic compound having a hole-transport property and the second substance having an electron acceptor property with respect to the first substance, for the hole-injection layers of light-emitting elements. Note that the maximum current efficiency was normalized by the maximum current efficiency of the light-emitting element 1. FIG. 18 shows the plot.

TABLE 3

Normalized current efficiency

| | HOMO (eV) | OMOx | HAT-CN |
|---|---|---|---|
| DBT3P-II | −6.22 | 1 | 0.00040 |
| | | (Light-emitting | (Comparative |
| | | element 1) | light-emitting |
| | | | element 1) |
| CBP | −5.87 | 0.53 | 0.00031 |
| | | (Light-emitting | (Comparative |
| | | element 2) | light-emitting |
| | | | element 2) |
| PCPPn | −5.8 | 0.16 | 0.00020 |
| | | (Light-emitting | (Comparative |
| | | element 3) | light-emitting |
| | | | element 3) |
| NPB | −5.38 | 0.019 | 0.00013 |
| | | (Light- emitting | (Comparative |
| | | element 4) | light-emitting |
| | | | element 4) |

The results revealed that the current efficiency is correlated with the HOMO level in the case of the elements including OMOx and that the current efficiency is noticeably increased as the HOMO level of the hole-transport layer becomes deep. In contrast, light emission from the quantum dots was hardly observed in the elements including HAT-CN.

According to the above, it is found that the hole-injection layer containing a composite material of the first substance which is an organic compound having a hole-transport property and the second substance having an electron acceptor property with respect to the first substance is effective for efficient hole injection into the light-emitting layer containing the quantum dots for light emission. It is also found that the use of OMOx containing a hole-transport material having a deep HOMO level for the hole-injection layer can provide preferable results and that a hole-transport material having a deep HOMO level is preferably used also for the hole-transport layer. In the case of using the quantum dots used in this example, light emission from the quantum dots is considerable when the first substance whose HOMO level is deeper than that of PCPPn was used, and the current efficiency was increased as the HOMO level becomes deep. This means that it is preferable to use the first substance having a HOMO level comparable to or deeper than the valence band maximum of the quantum dot.

With the use of OMOx, a carrier was able to be injected directly into the light-emitting layer containing the quantum dots having deep VB and CB easily, leading to successful light emission in the QLED element. It is found that the use of OMOx is particularly effective in injecting a hole into VB of the quantum dot and that the use of a hole-transport material having a HOMO level lower than −5.7 eV is effective. The efficiency is correlated with the HOMO level of the hole-transport material and is increased as the HOMO level becomes deeper.

This application is based on Japanese Patent Application serial no. 2015-172107 filed with Japan Patent Office on Sep. 1, 2015, Japanese Patent Application serial no. 2015-233260 filed with Japan Patent Office on Nov. 30, 2015, and Japanese Patent Application serial no. 2016-050742 filed with Japan Patent Office on Mar. 15, 2016, the entire contents of which are hereby incorporated by reference.

What is claimed is:

1. A light-emitting element comprising:
an anode;
a cathode; and
an EL layer,
wherein the EL layer is between the anode and the cathode,
wherein the EL layer comprises a light-emitting layer and a hole-injection layer,
wherein the hole-injection layer is between the light-emitting layer and the anode,
wherein the light-emitting layer contains a light-emitting substance,
wherein the hole-injection layer contains a first substance which is an organic compound having a hole-transport property and a second substance which is a substance having an electron acceptor property with respect to the first substance, and
wherein the light-emitting substance is a quantum dot.

2. The light-emitting element according to claim 1, wherein the second substance is a transition metal oxide or an oxide of a metal belonging to any of Groups 4 to 8 in the periodic table.

3. The light-emitting element according to claim 1, wherein the second substance is one or more of a vanadium oxide, a niobium oxide, a tantalum oxide, a chromium oxide, a molybdenum oxide, a tungsten oxide, a manganese oxide, a rhenium oxide, a titanium oxide, a ruthenium oxide, a zirconium oxide, a hafnium oxide, and a silver oxide.

4. The light-emitting element according to claim 1, wherein the second substance is a molybdenum oxide.

5. The light-emitting element according to claim 1, wherein a HOMO level of the first substance is greater than or equal to −7.0 eV and less than or equal to −5.7 eV.

6. The light-emitting element according to claim 1, wherein the first substance has a hole mobility of greater than or equal to 10⁻⁶ cm²/Vs.

7. The light-emitting element according to claim 1,
wherein the first substance is one of a heterocyclic compound having a dibenzothiophene skeleton or a dibenzofuran skeleton; an aromatic hydrocarbon having one or more of a carbazole skeleton, a fluorene skeleton, a naphthalene skeleton, a phenanthrene skeleton, and a triphenylene skeleton; and an organic compound comprising 4 to 25 benzene rings,
wherein all rings included in the organic compound are benzene rings.

8. The light-emitting element according to claim 1, wherein the first substance does not have an arylamine skeleton.

9. The light-emitting element according to claim 1, wherein the quantum dot has a core-shell structure.

10. The light-emitting element according to claim 1, wherein the light-emitting layer is in contact with the hole-injection layer.

11. The light-emitting element according to claim 1, further comprising:
a hole-transport layer between the light-emitting layer and the hole-injection layer,
wherein the hole-transport layer contains a third substance which is an organic compound having a hole-transport property.

12. The light-emitting element according to claim 11, wherein the third substance is the same substance as the first substance.

13. A light-emitting device comprising:
the light-emitting element according to claim 1; and
a transistor or a substrate.

14. An electronic device comprising:
the light-emitting device according to claim 13; and
a sensor, an operation button, a speaker, or a microphone.

15. A lighting device comprising:
the light-emitting device according to claim 13; and
a housing.

16. A light-emitting element comprising:
an anode;
a cathode; and
an EL layer,
wherein the EL layer is between the anode and the cathode,
wherein the EL layer comprises a light-emitting layer and a hole-injection layer,
wherein the hole-injection layer is between the light-emitting layer and the anode,
wherein the light-emitting layer contains a light-emitting substance,
wherein the hole-injection layer contains a first substance which is an organic compound having a hole-transport property and a second substance which is a substance having an electron acceptor property with respect to the first substance,
wherein the light-emitting substance is a quantum dot, and
wherein a HOMO level of the first substance is comparable to or deeper than valence band maximum of the quantum dot.

17. A light-emitting element comprising:
an anode;
a cathode; and
an EL layer,
wherein the EL layer is between the anode and the cathode,
wherein the EL layer comprises a light-emitting layer and a hole-injection layer,
wherein the hole-injection layer is between the light-emitting layer and the anode,
wherein the light-emitting layer contains a light-emitting substance,
wherein the hole-injection layer contains a first substance which is an organic compound having a hole-transport property and a second substance which is a substance having an electron acceptor property with respect to the first substance,
wherein the light-emitting substance is a quantum dot,
wherein a HOMO level of the first substance is comparable to or deeper than valence band maximum of the quantum dot, and
wherein the second substance is a molybdenum oxide.
